(19) United States
(12) Patent Application Publication
(10) Pub. No.: US 2024/0114226 A1
(43) Pub. Date: Apr. 4, 2024

(54) INTEGRATED SENSING AND DISPLAY SYSTEM

(71) Applicant: Meta Platforms Technologies, LLC, Menlo Park, CA (US)

(72) Inventors: Andrew Samuel Berkovich, Bellevue, WA (US); Warren Andrew Hunt, Woodinville, WA (US); Daniel Morgan, Seattle, WA (US); Shlomo Alkalay, Redmond, WA (US); Jack Thomas Lavier, Sammamish, WA (US)

(73) Assignee: Meta Platforms Technologies, LLC, Menlo Park, CA (US)

(21) Appl. No.: 17/564,889

(22) Filed: Dec. 29, 2021

Related U.S. Application Data
(60) Provisional application No. 63/131,937, filed on Dec. 30, 2020.

(51) Int. Cl. H04N 5/225; G06F 3/01; G06V 10/25; G09G 3/32; H01L 23/00; H01L 27/146; H01L 27/15; H04N 5/232

(52) U.S. Cl. CPC H04N 5/2257; G06F 3/013; G06V 10/25; G09G 3/32; H01L 24/08; H01L 24/16; H01L 27/14618; H01L 27/14634; H01L 27/14636; H01L 27/156; H04N 5/2252; H04N 5/232; G09G 2360/18; H01L 2224/08145; H01L 2224/16145

(57) ABSTRACT

In one example, an apparatus for integrating sensing and display system includes a first semiconductor layer that includes an image sensor; a second semiconductor layer that includes a display; a third semiconductor layer that includes compute circuits configured to support an image sensing operation by the image sensor and a display operation by the display; and a semiconductor package that encloses the first, second, and third semiconductor layers, the semiconductor package further including a first opening to expose the image sensor and a second opening to expose the display. The first, second, and third semiconductor layers form a first stack structure along a first axis. The third semiconductor layer is sandwiched between the first semiconductor layer and the second semiconductor layer in the first stack structure.

### CROSS-REFERENCE TO RELATED APPLICATIONS

This application claims priority to U.S. Provisional Patent Application 63/131,937, titled “Integrated Sensing and Display System,” filed Dec. 30, 2020, the entirety of which is incorporated herein by reference

### BACKGROUND

A computing system, such as a mobile device, typically includes various types of sensors, such as an image sensor, a motion sensor, etc., to generate sensor data about the operation conditions of the mobile device. The computing system can include a display to output certain contents. The computing system may operate an application that can determine the operation conditions based on the sensor data, and generate the contents accordingly. For example, a virtual reality (VR)/mixed reality (MR)/augmented reality (AR) application can determine the location of a user of the mobile device based on the sensor data, and generate virtual or composite images including virtual contents based on the location, to provide an immersive experience.

The application can benefit from increased resolutions and operation speeds of the sensors and the display. However, various constraints, such as area and power constraints imposed by the mobile device, can limit the resolution and operation speeds of the sensors and the displays, which in turn can limit the performance of the application that relies on the sensors and the display to provide inputs and outputs as well as user experience SUMMARY

The disclosure relates generally to a sensing and display system, and more specifically, an integrated sensing and display system.

In one example, an apparatus is provided. The apparatus includes a first semiconductor layer that includes an image sensor; a second semiconductor layer that includes a display; a third semiconductor layer that includes compute circuits configured to support an image sensing operation by the image sensor and a display operation by the display; and a semiconductor package that encloses the first, second, and third semiconductor layers, the semiconductor package further including a first opening to expose the image sensor and a second opening to expose the display. The first, second, and third semiconductor layers form a first stack structure along a first axis. The third semiconductor layer is sandwiched between the first semiconductor layer and the second semiconductor layer in the first stack structure.

In some aspects, the first semiconductor layer includes a first semiconductor substrate and a second semiconductor substrate forming a second stack structure along the first axis, the second stack structure being a part of the first stack structure. The first semiconductor substrate includes an array of pixel cells. The second semiconductor substrates includes processing circuits to process outputs of the array of pixel cells.

In some aspects, the first semiconductor substrate includes at least one of: silicon or germanium.

In some aspects, the first semiconductor layer further includes a motion sensor.

In some aspects, the first semiconductor layer includes a semiconductor substrate that includes: a micro-electromechanical system (MEMS) to implement the motion sensor; and a controller to control an operation of the MEMS and to collect sensor data from the MEMS.

In some aspects, the second semiconductor layer includes a semiconductor substrate that includes an array of light emitting diodes (LED) to form the display.

In some aspects, the semiconductor substrate forms a device layer. The second semiconductor layer further includes a thin-film circuit layer on the device layer configured to transmit control signals to the array of LEDs.

In some aspects, the device layer comprises a groups III V material. The thin-film circuit layer comprises indium gallium zinc oxide (IGZO) thin-film transistors (TFTs).

In some aspects, the compute circuits include a sensor compute circuit and a display compute circuit. The sensor compute circuit includes an image sensor controller configured to control the image sensor to perform the image sensing operation to generate a physical image frame. The display compute circuit includes a content generation circuit configured to generate an output image frame based on the physical image frame, and a rendering circuit configured to control the display to display the output image frame.

In some aspects, the compute circuits include a frame buffer. The image sensor controller is configured to store the physical image frame in the frame buffer. The content generation circuit is configured to replace one or more pixels of the physical image frame in the frame buffer to generate the output image frame, and to store the output image frame in the frame buffer. The rendering circuit is configured to read the output image frame from the frame buffer and to generate display control signals based on the output image frame read from the frame buffer.

In some aspects, the sensor compute circuit includes a sensor data processor configured to determine pixel locations of a region of interest (ROI) that enclose a target object in the physical image frame. The image sensor controller is configured to enable a subset of pixel cells of an array of pixel cells of the image sensor to capture a subsequent physical frame based on the pixel locations of the ROI.

In some aspects, the content generation circuit is configured to generate the output image frame based on a detection of the target object by the sensor data processor.

In some aspects, the first semiconductor layer further includes a motion sensor. The sensor data processor is further configured to determine at least one of a state of motion or a location of the apparatus based on an output of the motion sensor. The image sensor controller is configured to enable the subset of pixel cells based on the at least one of a state of motion or a location of the apparatus.

In some aspects, the content generation circuit is configured to generate the output image frame based on the at least one of a state of motion or a location of the apparatus.

In some aspects, the first semiconductor layer is connected to the third semiconductor layer via 3D interconnects.

In some aspects, the first semiconductor layer is connected to the third semiconductor layer via 2.5D interconnects.

In some aspects, the third semiconductor layer is connected to the second semiconductor layer via metal bumps.

In some aspects, the apparatus further comprises a laser diode adjacent to the image sensor and configured to project structured light.

In some aspects, the apparatus further comprises a light emitting diode (LED) adjacent to the display to support an eye-tracking operation.

In some aspects, the third semiconductor layer further includes a power management circuit.

In some aspects, the image sensor is divided into a plurality of tiles of image sensing elements. The display is divided into a plurality of tiles of display elements. A frame buffer of the compute circuits is divided into a plurality of tile frame buffers. Each tile frame buffer is directly connected to a corresponding tile of image sensing element and a corresponding tile of display elements. Each tile of image sensing elements is configured to store a subset of pixels of a physical image frame in the corresponding tile frame buffer. Each tile of display elements is configured to output a subset of pixels of an output image frame stored in the corresponding tile frame buffer.

In some examples, a method of generating an output image frame is provided. The method comprises: generating, using an image sensor, an input image frame, the image sensor comprising a plurality of tiles of image sensing elements, each tile of image sensing elements being connected to a corresponding tile frame buffer which is also connected to a corresponding tile of display elements of a display; storing, using each tile of image sensing elements, a subset of pixels of the input image frame at the corresponding tile frame buffer in parallel; replacing, by a content generator, at least some of the pixels of the input image frame stored at the tile frame buffers to generate the output image frame; and controlling each tile of display elements to fetch a subset of pixels of the output image frame from the corresponding tile frame buffer to display the output image frame.

These illustrative examples are mentioned not to limit or define the scope of this disclosure, but rather to provide examples to aid understanding thereof. Illustrative examples are discussed in the Detailed Description, which provides further description. Advantages offered by various examples may be further understood by examining this specification.

### BRIEF DESCRIPTION OF THE DRAWINGS

Illustrative embodiments are described with reference to the following figures.

FIG. 1A and FIG. 1B are diagrams of an embodiment of a near-eye display.

FIG. 2 is an embodiment of a cross section of the near-eye display.

FIG. 3 illustrates an isometric view of an embodiment of a waveguide display with a single source assembly.

FIG. 4 illustrates a cross section of an embodiment of the waveguide display.

FIG. 5 is a block diagram of an embodiment of a system including the near-eye display.

FIG. 6A, FIG. 6B, FIG. 6C, and FIG. 6D illustrate examples of an image sensor and its operations.

FIG. 7A and FIG. 7B illustrate an example of a display system and its operations.

FIG. 8A, FIG. 8B and FIG. 8C example components of a mobile device and its operations.

FIG. 9 illustrates examples of an integrated sensing and display system.

FIG. 10 illustrates examples of internal components of an integrated sensing and display system of FIG. 9.

FIG. 11 illustrates examples of internal components of an integrated sensing and display system of FIG. 9.

FIG. 12A and FIG. 12B illustrate examples of the internal components of the integrated sensing and display system of FIG. 9.

FIG. 13 illustrates an example of a timing diagram of operations of the integrated sensing and display system of FIG. 9.

FIG. 14A and FIG. 14B illustrate examples of a distributed sensing and display system and its operations.

FIG. 15 illustrates an example of a method of generating an output image frame.

The figures depict embodiments of the present disclosure for purposes of illustration only. One skilled in the art will readily recognize from the following description that alternative embodiments of the structures and methods illustrated may be employed without departing from the principles of, or benefits touted in, this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

In the following description, for the purposes of explanation, specific details are set forth to provide a thorough understanding of certain inventive embodiments. However, it will be apparent that various embodiments may be practiced without these specific details. The figures and description are not intended to be restrictive.

As described above, a computing system, such as a mobile device, typically includes various types of sensors, such as an image sensor, a motion sensor, etc., to generate sensor data about the operation conditions of the mobile device. The computing system can also include a display to output certain contents. The mobile device may also operate an application that receives sensor data from the sensors, generates contents based on the sensor data, and outputs the contents via the display.

One example of such an application is a VR/MR/AR application, which can generate virtual content based on the sensor data of the mobile device to provide user a simulated experience of being in a virtual world, or in a hybrid world having a mixture of physical objects and virtual objects. For example, a mobile device may be in the form of, for example, a head-mounted display (HMD), smart glasses, etc., to be worn by a user and covering the user's eyes. The HMD may include image sensors to capture images of a physical scene surrounding the user. The HMD may also include a display to output the images of the scene. Depending on the user's orientation/pose, the HMD may capture images from different angles of the scene and display the images to the user, thereby simulating the user's vision. To provide a VR/MR/AR experience, the application can determine various information, such as the orientation/pose of the user, location of the scene, physical objects present in a scene, etc., and generate contents based on the information. For example, the application can generate a virtual image representing a virtual scene to replace the physical scene the mobile device is in, and display the virtual image. As another example, the application may generate a composite image including a part of the image of the physical scene as well as virtual contents, and display the composite image to the user. The virtual contents may include, for example, a virtual object to replace a physical object in the physical scene, texts or other image data to annotate a physical object in the physical scene, etc. As the virtual/composite images displayed to the user change as the user moves or changes orientation/pose, the application can provide the user with a simulated experience of being immersed in a virtual/hybrid world.

The VR/MR/AR application, as well as the immersive experience provided by the application, can benefit from increased resolutions and operation speeds of the image sensor and the displays. By increasing the resolutions of the image sensor and the displays, more detailed images of the scene can be captured and (in the case of AR/MR) displayed to the user to provide improved simulation of vision. Moreover, in the case of VR, a more detailed virtual scene can be constructed based on the captured images and displayed to user. Also, by increasing the operation speeds of the image sensor and the display, the images captured and displayed can change more responsively to changes in the location/orientation/pose of the user. All these can improve the user's simulated experience of being immersed in a virtual/hybrid world.

Although a mobile device application can benefit from the increased resolutions and operation speeds of the image sensor and the displays, various constraints, such as area and power constraints imposed by the mobile device, can limit the resolution and operation speeds of the image sensor and the displays. Specifically, an image sensor typically includes an array of image sensing elements (e.g., photodiodes), whereas a display typically includes an array of display elements (e.g., light emitting diodes (LED)). The mobile device further includes compute circuits, such as image processing circuits, rendering circuits, memory, etc., that support the operations of the display elements and image sensing elements. Due to the small form factors of the mobile device/HMD, limited space is available to fit in the image sensor, the displays, and their compute circuits, which in turn can limit the numbers of image sensing elements and display elements, as well as the quantities of computation and memory resources included in the compute circuits, all of which can limit the achievable image sensing and display resolutions. The limited available power of a mobile device also constrains the numbers of image sensing elements and display elements.

In addition, operating the image sensor and the display at high frame rate requires moving a large quantity of image data and content data within the mobile device at a high data rate. But moving those data at a high data rate can involve massive compute resources and power consumption, especially when the data are moved over discrete electrical buses (e.g., a mobile industry processor interface (MIPI)) within the mobile device at a high data rate. Due to the limited available power and computation resources at the mobile device, the data rate for movement of image data and content data within the mobile device is also limited, which in turn can limit the achievable speeds of operation, as well as the achievable resolutions, of the image sensor and the displays.

This disclosure relates to an integrated system that can address at least some of the issues above. Specifically, a system may include a sensor, compute circuits, and a display. The compute circuits can include sensor compute circuits to interface with the sensor and display compute circuits to interface with the display. The compute circuits can receive sensor data from the sensor and generate content data based on the sensor data, and provide the content data to the display. The sensor can be formed on a first semiconductor layer and the display can be formed on a second semiconductor layer, whereas the compute circuit can be formed on a third semiconductor layer. The first, second, and third semiconductor layers can form a stack structure with the third semiconductor layer sandwiched between the first semiconductor substrate and the second semiconductor layer. Moreover, each of first, second, and third semiconductor layers can also include one or more semiconductor substrates stacked together. The stack structure can be enclosed at least partially within a semiconductor package having at least a first opening to expose the display. The integrated system can be part of a mobile device (e.g., a head-mounted display (HMD)), and the semiconductor package can have input/output (I/O) pins to connect with other components of the mobile device, such as a host processor that executes a VR/AR/MR application.

In some examples, the first, second, and third semiconductor layers can be fabricated with heterogeneous technologies (e.g., different materials, different process nodes) to form a heterogeneous system. The first semiconductor layer can include various types of sensor devices, such as an array of image sensing elements, each including one or more photodiodes as well as circuits (e.g., analog-to-digital converters) to digitize the sensor outputs. Depending the sensing wavelength, the first semiconductor substrate can include various materials such as silicon, Germanium, etc. In addition, the first semiconductor substrate may also include a motion sensor, such as an inertial motion unit (IMU), which can include a micro-electromechanical system (MEMS). Both the array of image sensing elements and the MEMS of the motion sensor can be formed on a first surface of the first semiconductor substrate facing away from the second and third semiconductor substrates, and the semiconductor package can have a second opening to expose the array of image sensing elements.

Moreover, the second semiconductor layer can include an array of display elements each including a light emitting diode (LED) to form the display, which can be in the form of tiled displays or a single display for both left and right eyes. The second semiconductor layer may include a sapphire substrate or a gallium nitride (GaN) substrate. The array of display elements can be formed in one or more semiconductor layers on a second surface of the second semiconductor substrate facing away from the first and third semiconductor substrates. The semiconductor layers may include various groups III-V material depending on the color of light to be emitted by the LED such as (GaN), indium gallium nitride (InGaN), aluminum gallium indium phosphide (AlInGaP), Lead Selenide (PbSe), Lead Sulfide (PbS), Graphene, etc. In some examples, second semiconductor layer may further include indium gallium zinc oxide (IGZO) thin-film transistors (TFTs) to transmit control signals to the array of display elements. In some examples, the second semiconductor layer may also include a second array of image sensing elements on the second surface of the second semiconductor layer to collect images of the user's eyes while the user is watching the display.

Further, the third semiconductor layer can include digital logics and memory cells to implement the compute circuits. The third semiconductor layer may include silicon transistor devices, such as a fin field-effect transistor (FinFET), a Gate-all-around FET (GAAFET), etc., to implement the digital logics, as well as memory devices, such as MRAM device, ReRAM device, SRAM devices, etc., to implement the memory cells. The third semiconductor layer may also include other transistor devices, such as analog transistors, capacitors, etc., to implement analog circuits, such as analog-to-digital converters (ADC) to quantize the sensor signals, display drivers to transmit current to the LEDs of the display elements, etc.

In addition to sensor, display, and compute circuits, the integrated system may include other components to support the VR/AR/MR application on the host processor. For example, the integrated system may include one or more illuminators for active sensing. For example, the integrated system may include a laser diode (e.g., vertical-cavity, surface-emitting lasers (VCSELs)) to project light for depth-sensing. The laser diode can be formed on the first surface of the first semiconductor substrate to project light (e.g., structured light) into the scene, and the image sensor on the first surface of the first semiconductor layer can detect light reflected from the scene. As another example, the integrated system may include a light emitting diode (LED) to project light towards the user's eyes when the user watches the display. The LED can be formed on the second surface of the second semiconductor layer facing the user's eyes. Images of the eyes can then be captured by the image sensor on the second surface to support, for example, eye tracking. In addition, the integrated system can include various optical components, such as lenses and filters, positioned over the image sensor on the first semiconductor layer and the display on the second semiconductor layer to control the optical properties of the light entering the lenses and exiting the display. In some examples, the lenses can be wafer level optics.

The integrated system further includes first interconnects to connect between the first semiconductor layer and the third semiconductor layer to enable communication between the image sensor in the first semiconductor layer and the sensor compute circuits in the third semiconductor layer. The integrated system also includes second interconnects to connect between the third semiconductor layer and the second semiconductor layer to enable communication between the display/image sensor in the second semiconductor layer and the sensor/display compute circuits in the third semiconductor layer. Various techniques can be used to implement the first and second interconnects to connect between the third semiconductor layer and each of the first and second semiconductor layers. In some examples, at least one of the first and second interconnects can include 3D interconnects, such as through silicon vias (TSVs), micro-TSVs, a Copper-Copper bump, etc. In some examples, at least one of first and second interconnects can include 2.5D interconnects, such as an interposer. In such examples, the system can include multiple semiconductor substrates, each configured as a chiplet. For example, the array of image sensing elements of the image sensor can be formed in one chiplet or divided into multiple chiplets. Moreover, the motion sensor can also be formed in another chiplet. Each chiplet can be connected to an interposer via, for example, micro-bumps. The interposer is then connected to the third semiconductor layer via, for example, micro-bumps.

As described above, the compute circuits in the third semiconductor layer can include sensor compute circuits to interface with the sensor and display compute circuits to interface with the display. The sensor compute circuits can include, for example, an image sensor controller, an image sensor frame buffer, a motion data buffer, and a sensor data processor. Specifically, the image sensor controller can control the image sensing operations performed by the image sensor by, for example, providing global signals (e.g., clock signals, various control signals) to the image sensor. The image sensor controller can also enable a subset of the array of image sensing elements to generate a sparse image frame. The image sensor frame buffer can store one or more image frames generated by the array of image sensing elements. The motion data buffer can store motion measurement data (e.g., pitch, roll, yaw) measured by the IMU. The sensor data processor can process the image frames and motion measurement data. For example, the sensor data processor can include an image processor to process the image frames to determine the location and the size of a region of interest (ROI) enclosing a target object, and transmit image sensor control signals back to the image sensor to enable the subset of image sensing elements corresponding to the ROI. The target object can be defined by the application on the host processor, which can send the target object information to the system. In addition, the sensor data processor can include circuits such as, for example, a Kalman filter, to determine a location, an orientation, and/or a pose of the user based on the IMU data. The sensor compute circuits can transmit the processing results, such as location and size of ROI, location, orientation and/or pose information of the user, to the display compute circuits.

The display compute circuits can generate (or update) content based on the processing results from the sensor compute circuits, and generate display control signals to the display to output the content. The display compute circuits can include, for example, a content generation circuit, a display frame buffer, a rendering circuit, etc. Specifically, the content generation circuit can receive a reference image frame, which can be a virtual image frame from the host processor, a physical image frame from the image sensor, etc. The content generation circuit can generate an output image frame based on the reference image frame, as well as the sensor processing result. For example, in a case where the virtual image frame is received from the host processor, the content generation circuit can perform a transformation operation on the virtual image frame to reflect a change in the user's viewpoint based on the location, orientation and/or pose information of the user. As another example, in a case where a physical image frame is received from the image processor, the content generation circuit can generate the output image frame as a composite image based on adding virtual content such as, for example, replacing a physical object with a virtual object, adding virtual annotations, etc. The content generation circuit can also perform additional post-processing of the output image frame to, for example, compensate for optical and motion warping effects. The content generation circuit can then store the output image frame at the display frame buffer. The rendering circuit can include control logic and LED driver circuits. The control logic can read pixels of the output image frame from the frame buffer according to a scanning pattern, and transmit display control signals to the LED driver circuits to render the output image frame.

In some examples, the sensor, the compute circuits, and the display can be arranged to form a distributed sensing and display system, in which the display is divided into tiles of display elements and the image sensor is divided into tiles of image sensing elements. Each tile of display elements in the second semiconductor substrate is directly connected, via the second on-chip interconnects, to a corresponding tile memory in the third semiconductor substrate. Each tile memory is, in turn, connected to a corresponding tile of image sensing elements in the first semiconductor substrate. To support an AR/MR application, each tile of image sensing elements can generate a subset of pixel data of a scene and store the subset of pixel data in the corresponding tile memory. The content generation circuit can edit a subset of the stored pixel data to add in the virtual contents. The rendering circuit can then transmit display controls to each tile of display elements based on the pixel data stored in the corresponding tile memories.

With the disclosed techniques, an integrated system in which sensor, compute, and display are integrated within a semiconductor package can be provided. Such an integrated system can improve the performance of the sensor and the display while reducing footprint and reducing power consumption. Specifically, by putting sensor, compute, and display within a semiconductor package, the distances travelled by the data between the sensor and the compute and between the compute and the display can be greatly reduced, which can improve the speed of transfer of data. The speed of data transfer can be further improved by the 2.5D and 3D interconnects, which can provide high-bandwidth and short-distance routes for the transfer of data. All these allow the image sensor and the display to operate at a higher frame to improve their operation speeds. Moreover, as the sensor and the display are integrated within a rigid stack structure, relative movement between the sensor and the display (e.g., due to thermal expansion) can be reduced, which can reduce the need to calibrate the sensor and the display to account for the movement.

In addition, the integrated system can reduce footprint and power consumption. Specifically, by stacking the compute circuits and the sensors on the back of the display, the overall footprint occupied by the sensors, the compute circuits, and the display can be reduced especially compared with a case where the display, the sensor, and the compute circuits are scattered at different locations. The stacking arrangements are also likely to achieve the minimum and optimum overall footprint, given that the display typically have the largest footprint (compared with sensor and compute circuits). Moreover, the image sensors can be oriented to face an opposite direction from the display to provide simulated vision, which allows placing the image sensors on the back of the display, while placing the motion sensor on the back of the display typically does not affect the overall performance of the system.

Moreover, in addition to improving the data transfer rate, the 2.5D/3D interconnects between the semiconductor substrates also allow the data to be transferred more efficiently compared with, for example, discrete buses such as those defined under the MIPI specification. For example, C-PHY Mobile Industry Processor Interface (MIPI) requires a few pico-Joule (pJ)/bit while wireless transmission through a 60 GHz link requires a few hundred pJ/bit. In contrast, due to the high bandwidth and the short routing distance provided by the on-chip interconnects, the power consumed in the transfer of data over 2.5D/3D interconnects is typically just a fraction of pJ/bit. Furthermore, due to the higher transfer bandwidth and reduced transfer distance, the data transfer time can also be reduced as a result, which allows support circuit components (e.g., clocking circuits, signal transmitter and receiver circuits) to be powered off for a longer duration to further reduce the overall power consumption of the system.

The integrated system also allows implementation of a distributed sensing and display system, which can further improve the system performance. Specifically, compared with a case where the image sensors store an image at a centralized frame buffer from which the display fetches the image, which typically requires sequential accesses of the frame buffer to write and read a frame, a distributed sensing and display system allows each tile of image sensing elements to store a subset of pixel data of a scene into each corresponding tile memory in parallel. Moreover, each tile of display elements can also fetch the subset of pixel data from the corresponding tile memory in parallel. The parallel access of the tile memories can speed up the transfer of image data from the image sensor to the displays, which can further increase the operation speeds of the image sensor and the displays.

The disclosed techniques may include or be implemented in conjunction with an AR system. Artificial reality is a form of reality that has been adjusted in some manner before presentation to a user, which may include, for example, a VR, an AR, a MR, a hybrid reality, or some combination and/or derivatives thereof. Artificial reality content may include completely generated content or generated content combined with captured (e.g., real-world) content. The AR content may include video, audio, haptic feedback, or some combination thereof, any of which may be presented in a single channel or in multiple channels (such as stereo video that produces a 3D effect to the viewer). Additionally, in some embodiments, AR may also be associated with applications, products, accessories, services, or some combination thereof, that are used to, for example, create content in an AR and/or are otherwise used in (e.g., performing activities in) an AR. The AR system that provides the AR content may be implemented on various platforms, including a head-mounted display (HMD) connected to a host computer system, a standalone HMD, a mobile device or computing system, or any other hardware platform capable of providing artificial reality content to one or more viewers.

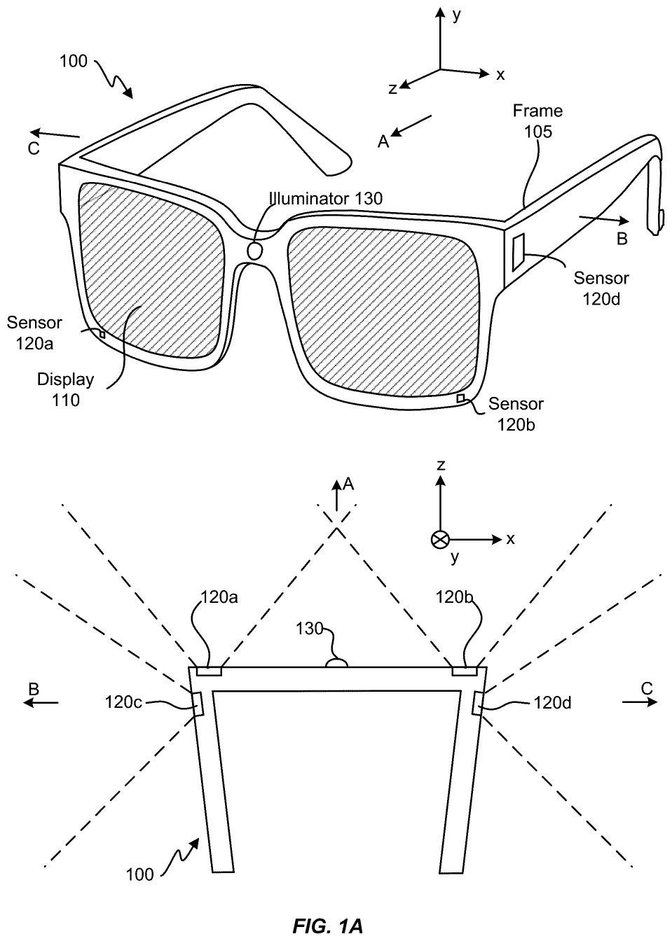

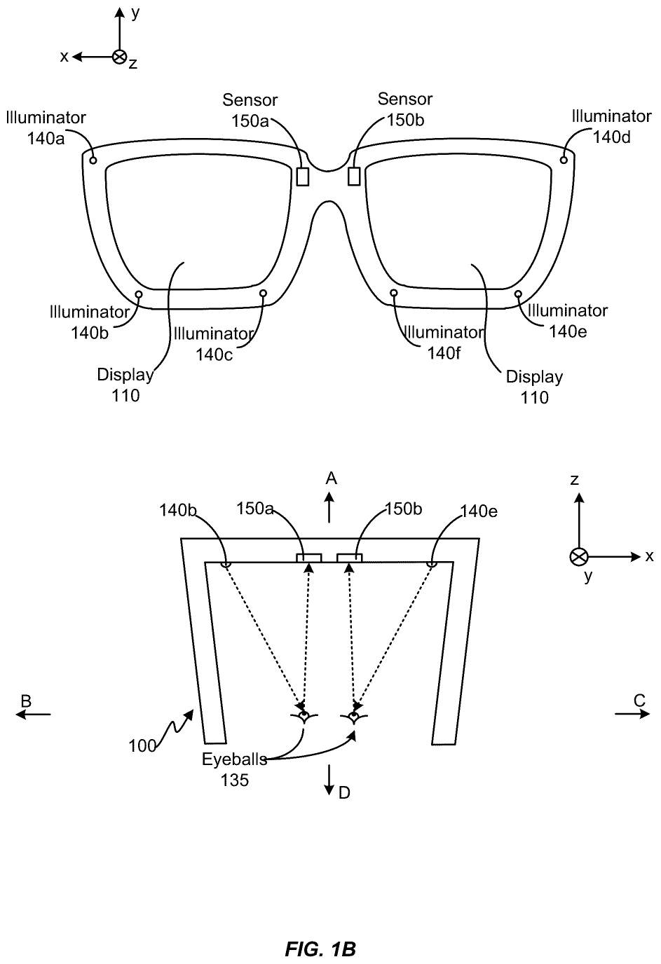

FIG. 1A is a diagram of an embodiment of a near-eye display 100. Near-eye display 100 presents media to a user. Examples of media presented by near-eye display 100 include one or more images, video, and/or audio. In some embodiments, audio is presented via an external device (e.g., speakers and/or headphones) that receives audio information from the near-eye display 100, a console, or both, and presents audio data based on the audio information. Near-eye display 100 is generally configured to operate as a VR display. In some embodiments, near-eye display 100 is modified to operate as an AR display and/or a MR display.

Near-eye display 100 includes a frame 105 and a display 110. Frame 105 is coupled to one or more optical elements. Display 110 is configured for the user to see content presented by near-eye display 100. In some embodiments, display 110 comprises a waveguide display assembly for directing light from one or more images to an eye of the user.

Near-eye display 100 further includes image sensors 120a, 120b, 120c, and 120d. Each of image sensors 120a, 120b, 120c, and 120d may include a pixel array configured to generate image data representing different fields of views along different directions. For example, sensors 120a and 120b may be configured to provide image data representing two fields of view towards a direction A along the Z axis, whereas sensor 120c may be configured to provide image data representing a field of view towards a direction B along the X axis, and sensor 120d may be configured to provide image data representing a field of view towards a direction C along the X axis.

In some embodiments, sensors 120a 120d can be configured as input devices to control or influence the display content of the near-eye display 100, to provide an interactive VR/AR/MR experience to a user who wears near-eye display 100. For example, sensors 120a-120d can generate physical image data of a physical environment in which the user is located. The physical image data can be provided to a location tracking system to track a location and/or a path of movement of the user in the physical environment. A system can then update the image data provided to display 110 based on, for example, the location and orientation of the user, to provide the interactive experience. In some embodiments, the location tracking system may operate a SLAM algorithm to track a set of objects in the physical environment and within a view of field of the user as the user moves within the physical environment. The location tracking system can construct and update a map of the physical environment based on the set of objects, and track the location of the user within the map. By providing image data corresponding to multiple fields of views, sensors 120a 120d can provide the location tracking system a more holistic view of the physical environment, which can lead to more objects to be included in the construction and updating of the map. With such an arrangement, the accuracy and robustness of tracking a location of the user within the physical environment can be improved.

In some embodiments, near-eye display 100 may further include one or more active illuminators 130 to project light into the physical environment. The light projected can be associated with different frequency spectrums (e.g., visible light, infra-red light, ultra-violet light, etc.), and can serve various purposes. For example, illuminator 130 may project light in a dark environment (or in an environment with low intensity of infrared (IR) light, ultraviolet (UV) light, etc.) to assist sensors 120a 120d in capturing images of different objects within the dark environment to, for example, enable location tracking of the user. Illuminator 130 may project certain markers onto the objects within the environment, to assist the location tracking system in identifying the objects for map construction/updating.

In some embodiments, illuminator 130 may also enable stereoscopic imaging. For example, one or more of sensors 120a or 120b can include both a first pixel array for visible light sensing and a second pixel array for infra-red (IR) light sensing. The first pixel array can be overlaid with a color filter (e.g., a Bayer filter), with each pixel of the first pixel array being configured to measure the intensity of light associated with a particular color (e.g., one of red, green or blue colors). The second pixel array (for IR light sensing) can also be overlaid with a filter that allows only IR light through, with each pixel of the second pixel array being configured to measure the intensity of IR lights. The pixel arrays can generate an RGB image and an IR image of an object, with each pixel of the IR image being mapped to each pixel of the RGB image. Illuminator 130 may project a set of IR markers on the object, the images of which can be captured by the IR pixel array. Based on a distribution of the IR markers of the object as shown in the image, the system can estimate a distance of different parts of the object from the IR pixel array, and generate a stereoscopic image of the object based on the distances. Based on the stereoscopic image of the object, the system can determine, for example, a relative position of the object with respect to the user, and can update the image data provided to display 100 based on the relative position information to provide the interactive experience.

As discussed above, near-eye display 100 may be operated in environments associated with a wide range of light intensities. For example, near-eye display 100 may be operated in an indoor environment or in an outdoor environment, and/or at different times of the day. Near-eye display 100 may also operate with or without active illuminator 130 being turned on. As a result, image sensors 120a 120d may need to have a wide dynamic range to be able to operate properly (e.g., to generate an output that correlates with the intensity of incident light) across a wide range of light intensities associated with different operating environments for near-eye display 100.

FIG. 1B is a diagram of another embodiment of near-eye display 100. FIG. 1B illustrates a side of near-eye display 100 that faces the eyeball(s) 135 of the user who wears near-eye display 100. As shown in FIG. 1B, near-eye display 100 may further include a plurality of illuminators 140a, 140b, 140c, 140d, 140e, and 140f. Near-eye display 100 further includes a plurality of image sensors 150a and 150b. Illuminators 140a, 140b, and 140c may emit lights of certain frequency range (e.g., NIR) towards direction D (which is opposite to direction A of FIG. 1A). The emitted light may be associated with a certain pattern, and can be reflected by the left eyeball of the user. Sensor 150a may include a pixel array to receive the reflected light and generate an image of the reflected pattern. Similarly, illuminators 140d, 140e, and 140f may emit NIR lights carrying the pattern. The NIR lights can be reflected by the right eyeball of the user, and may be received by sensor 150b. Sensor 150b may also include a pixel array to generate an image of the reflected pattern. Based on the images of the reflected pattern from sensors 150a and 150b, the system can determine a gaze point of the user, and update the image data provided to display 100 based on the determined gaze point to provide an interactive experience to the user.

As discussed above, to avoid damaging the eyeballs of the user, illuminators 140a, 140b, 140c, 140d, 140e, and 140f are typically configured to output lights of very low intensities. In a case where image sensors 150a and 150b comprise the same sensor devices as image sensors 120a 120d of FIG. 1A, the image sensors 120a 120d may need to be able to generate an output that correlates with the intensity of incident light when the intensity of the incident light is low, which may further increase the dynamic range requirement of the image sensors.

Moreover, the image sensors 120a 120d may need to be able to generate an output at a high speed to track the movements of the eyeballs. For example, a user's eyeball can perform a rapid movement (e.g., a saccade movement) in which there can be a quick jump from one eyeball position to another. To track the rapid movement of the user's eyeball, image sensors 120a 120d need to generate images of the eyeball at high speed. For example, the rate at which the image sensors generate an image frame (the frame rate) needs to at least match the speed of movement of the eyeball. The high frame rate requires short total exposure time for all of the pixel cells involved in generating the image frame, as well as high speed for converting the sensor outputs into digital values for image generation. Moreover, as discussed above, the image sensors also need to be able to operate at an environment with low light intensity.

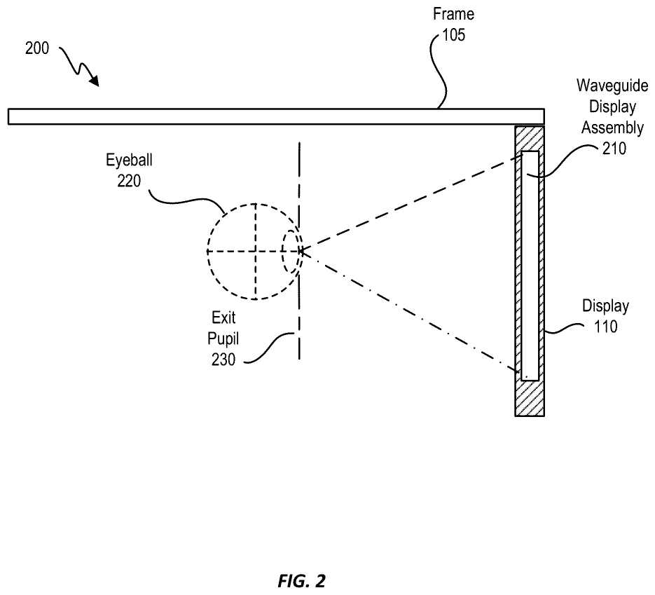

FIG. 2 is an embodiment of a cross section 200 of near-eye display 100 illustrated in FIGS. 1A-1B. Display 110 includes at least one waveguide display assembly 210. An exit pupil 230 is a location where a single eyeball 220 of the user is positioned in an eyebox region when the user wears the near-eye display 100. For purposes of illustration, FIG. 2 shows the cross section 200 associated with eyeball 220 and a single waveguide display assembly 210, but a second waveguide display is used for a second eye of a user.

Waveguide display assembly 210 is configured to direct image light to an eyebox located at exit pupil 230 and to eyeball 220. Waveguide display assembly 210 may be composed of one or more materials (e.g., plastic, glass.) with one or more refractive indices. In some embodiments, near-eye display 100 includes one or more optical elements between waveguide display assembly 210 and eyeball 220.

In some embodiments, waveguide display assembly 210 includes a stack of one or more waveguide displays including, but not restricted to, a stacked waveguide display, a varifocal waveguide display, etc. The stacked waveguide display is a polychromatic display (e.g., a red-green-blue (RGB) display) created by stacking waveguide displays whose respective monochromatic sources are of different colors. The stacked waveguide display is also a polychromatic display that can be projected on multiple planes (e.g., multi-planar colored display). In some configurations, the stacked waveguide display is a monochromatic display that can be projected on multiple planes (e.g., multi-planar monochromatic display). The varifocal waveguide display is a display that can adjust a focal position of image light emitted from the waveguide display. In alternate embodiments, waveguide display assembly 210 may include the stacked waveguide display and the varifocal waveguide display.

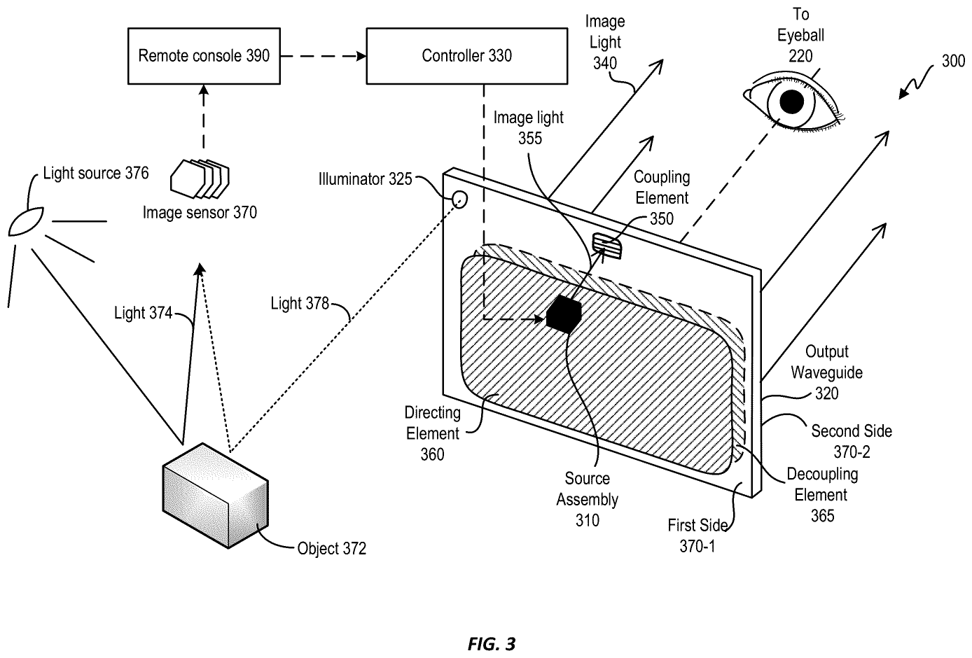

FIG. 3 illustrates an isometric view of an embodiment of a waveguide display 300. In some embodiments, waveguide display 300 is a component (e.g., waveguide display assembly 210) of near-eye display 100. In some embodiments, waveguide display 300 is part of some other near-eye display or other system that directs image light to a particular location.

Waveguide display 300 includes a source assembly 310, an output waveguide 320, and a controller 330. For purposes of illustration, FIG. 3 shows the waveguide display 300 associated with a single eyeball 220, but in some embodiments, another waveguide display separate, or partially separate, from the waveguide display 300 provides image light to another eye of the user.

Source assembly 310 generates image light 355. Source assembly 310 generates and outputs image light 355 to a coupling element 350 located on a first side 370-1 of output waveguide 320. Output waveguide 320 is an optical waveguide that outputs expanded image light 340 to an eyeball 220 of a user. Output waveguide 320 receives image light 355 at one or more coupling elements 350 located on the first side 370-1 and guides received input image light 355 to a directing element 360. In some embodiments, coupling element 350 couples the image light 355 from source assembly 310 into output waveguide 320. Coupling element 350 may be, for example, a diffraction grating, a holographic grating, one or more cascaded reflectors, one or more prismatic surface elements, and/or an array of holographic reflectors.

Directing element 360 redirects the received input image light 355 to decoupling element 365 such that the received input image light 355 is decoupled out of output waveguide 320 via decoupling element 365. Directing element 360 is part of, or affixed to, first side 370-1 of output waveguide 320. Decoupling element 365 is part of, or affixed to, second side 370-2 of output waveguide 320, such that directing element 360 is opposed to the decoupling element 365. Directing element 360 and/or decoupling element 365 may be, for example, a diffraction grating, a holographic grating, one or more cascaded reflectors, one or more prismatic surface elements, and/or an array of holographic reflectors.

Second side 370-2 represents a plane along an x-dimension and a y-dimension. Output waveguide 320 may be composed of one or more materials that facilitate total internal reflection of image light 355. Output waveguide 320 may be composed of for example, silicon, plastic, glass, and/or polymers. Output waveguide 320 has a relatively small form factor. For example, output waveguide 320 may be approximately 50 mm wide along the x-dimension, 30 mm long along y-dimension and 0.5-1 mm thick along a z-dimension.

Controller 330 controls scanning operations of source assembly 310. The controller 330 determines scanning instructions for the source assembly 310. In some embodiments, the output waveguide 320 outputs expanded image light 340 to the user's eyeball 220 with a large field of view (FOV). For example, the expanded image light 340 is provided to the user's eyeball 220 with a diagonal FOV (in x and y) of 60 degrees and/or greater and/or 150 degrees and/or less. The output waveguide 320 is configured to provide an eyebox with a length of 20 mm or greater and/or equal to or less than 50 mm; and/or a width of 10 mm or greater and/or equal to or less than 50 mm.

Moreover, controller 330 also controls image light 355 generated by source assembly 310, based on image data provided by image sensor 370. Image sensor 370 may be located on first side 370-1 and may include, for example, image sensors 120a 120d of FIG. 1A. Image sensors 120a 120d can be operated to perform 2D sensing and 3D sensing of, for example, an object 372 in front of the user (e.g., facing first side 370-1). For 2D sensing, each pixel cell of image sensors 120a 120d can be operated to generate pixel data representing an intensity of light 374 generated by a light source 376 and reflected off object 372. For 3D sensing, each pixel cell of image sensors 120a 120d can be operated to generate pixel data representing a time-of-flight measurement for light 378 generated by illuminator 325. For example, each pixel cell of image sensors 120a-120d can determine a first time when illuminator 325 is enabled to project light 378 and a second time when the pixel cell detects light 378 reflected off object 372. The difference between the first time and the second time can indicate the time-of-flight of light 378 between image sensors 120a 120d and object 372, and the time-of-flight information can be used to determine a distance between image sensors 120a 120d and object 372. Image sensors 120a 120d can be operated to perform 2D and 3D sensing at different times, and provide the 2D and 3D image data to a remote console 390 that may be (or may be not) located within waveguide display 300. The remote console may combine the 2D and 3D images to, for example, generate a 3D model of the environment in which the user is located, to track a location and/or orientation of the user, etc. The remote console may determine the content of the images to be displayed to the user based on the information derived from the 2D and 3D images. The remote console can transmit instructions to controller 330 related to the determined content. Based on the instructions, controller 330 can control the generation and outputting of image light 355 by source assembly 310 to provide an interactive experience to the user.

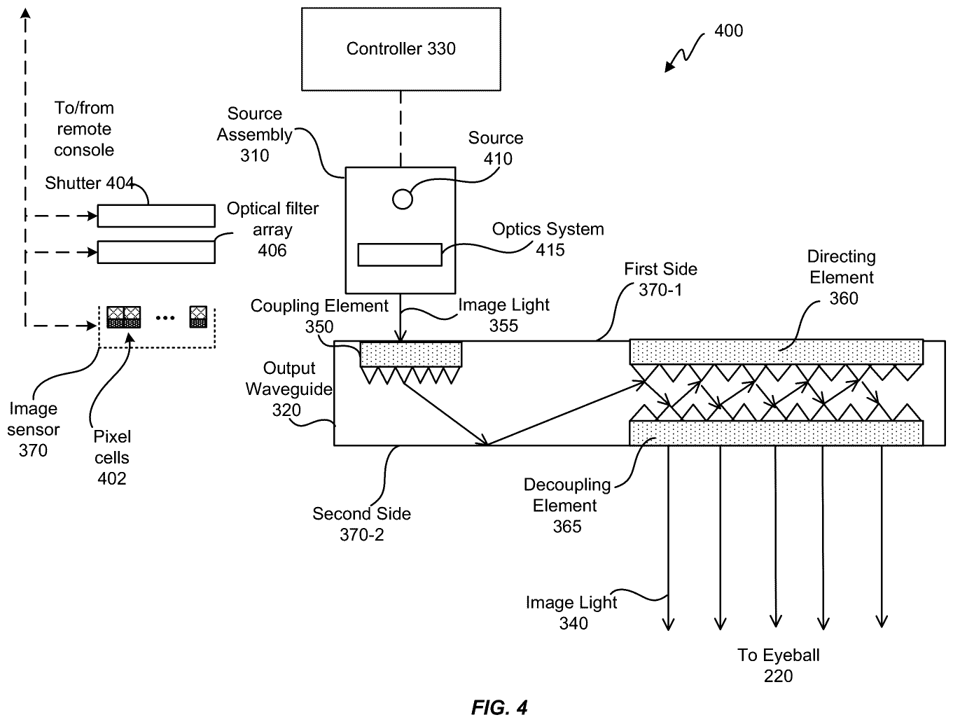

FIG. 4 illustrates an embodiment of a cross section 400 of the waveguide display 300. The cross section 400 includes source assembly 310, output waveguide 320, and image sensor 370. In the example of FIG. 4, image sensor 370 may include a set of pixel cells 402 located on first side 370-1 to generate an image of the physical environment in front of the user. In some embodiments, there can be a mechanical shutter 404 and an optical filter array 406 interposed between the set of pixel cells 402 and the physical environment. Mechanical shutter 404 can control the exposure of the set of pixel cells 402. In some embodiments, the mechanical shutter 404 can be replaced by an electronic shutter gate, as to be discussed below. Optical filter array 406 can control an optical wavelength range of light the set of pixel cells 402 is exposed to, as to be discussed below. Each of pixel cells 402 may correspond to one pixel of the image. Although not shown in FIG. 4, it is understood that each of pixel cells 402 may also be overlaid with a filter to control the optical wavelength range of the light to be sensed by the pixel cells.

After receiving instructions from the remote console, mechanical shutter 404 can open and expose the set of pixel cells 402 in an exposure period. During the exposure period, image sensor 370 can obtain samples of lights incident on the set of pixel cells 402, and generate image data based on an intensity distribution of the incident light samples detected by the set of pixel cells 402. Image sensor 370 can then provide the image data to the remote console, which determines the display content, and provide the display content information to controller 330. Controller 330 can then determine image light 355 based on the display content information.

Source assembly 310 generates image light 355 in accordance with instructions from the controller 330. Source assembly 310 includes a source 410 and an optics system 415. Source 410 is a light source that generates coherent or partially coherent light. Source 410 may be, for example, a laser diode, a vertical cavity surface emitting laser, and/or a light emitting diode.

Optics system 415 includes one or more optical components that condition the light from source 410. Conditioning light from source 410 may include, for example, expanding, collimating, and/or adjusting orientation in accordance with instructions from controller 330. The one or more optical components may include one or more lenses, liquid lenses, mirrors, apertures, and/or gratings. In some embodiments, optics system 415 includes a liquid lens with a plurality of electrodes that allows scanning of a beam of light with a threshold value of scanning angle to shift the beam of light to a region outside the liquid lens. Light emitted from the optics system 415 (and also source assembly 310) is referred to as image light 355.

Output waveguide 320 receives image light 355. Coupling element 350 couples image light 355 from source assembly 310 into output waveguide 320. In embodiments where coupling element 350 is a diffraction grating, a pitch of the diffraction grating is chosen such that total internal reflection occurs in output waveguide 320, and image light 355 propagates internally in output waveguide 320 (e.g., by total internal reflection), toward decoupling element 365.

Directing element 360 redirects image light 355 toward decoupling element 365 for decoupling from output waveguide 320. In embodiments where directing element 360 is a diffraction grating, the pitch of the diffraction grating is chosen to cause incident image light 355 to exit output waveguide 320 at angle(s) of inclination relative to a surface of decoupling element 365.

In some embodiments, directing element 360 and/or decoupling element 365 are structurally similar. Expanded image light 340 exiting output waveguide 320 is expanded along one or more dimensions (e.g., may be elongated along x-dimension). In some embodiments, waveguide display 300 includes a plurality of source assemblies 310 and a plurality of output waveguides 320. Each of source assemblies 310 emits a monochromatic image light of a specific band of wavelength corresponding to a primary color (e.g., red, green, or blue). Each of output waveguides 320 may be stacked together with a distance of separation to output an expanded image light 340 that is multi-colored.

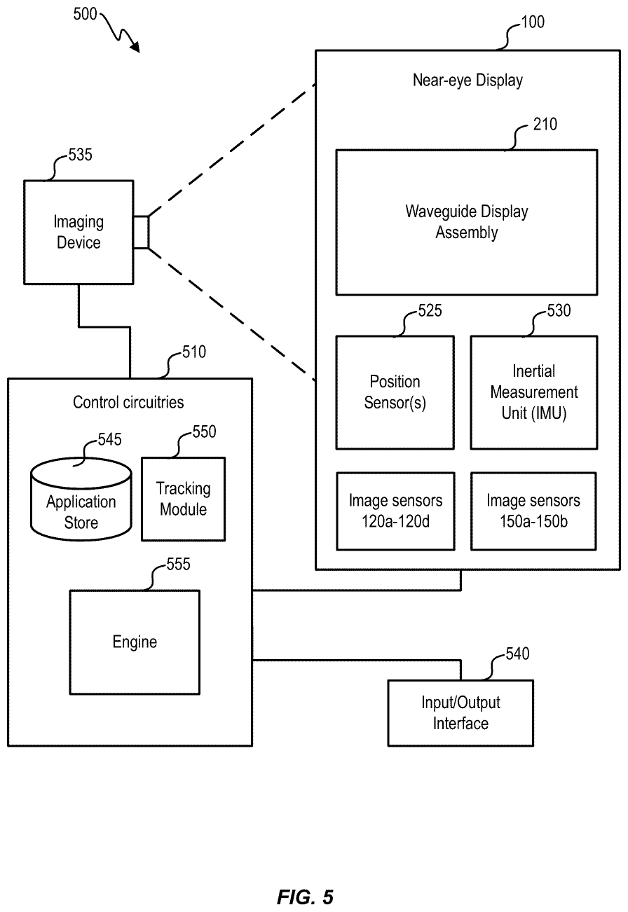

FIG. 5 is a block diagram of an embodiment of a system 500 including the near-eye display 100. The system 500 comprises near-eye display 100, an imaging device 535, an input/output interface 540, and image sensors 120a 120d and 150a 150b that are each coupled to control circuitries 510. System 500 can be configured as a head-mounted device, a mobile device, a wearable device, etc.

Near-eye display 100 is a display that presents media to a user. Examples of media presented by the near-eye display 100 include one or more images, video, and/or audio. In some embodiments, audio is presented via an external device (e.g., speakers and/or headphones) that receives audio information from near-eye display 100 and/or control circuitries 510 and presents audio data based on the audio information to a user. In some embodiments, near-eye display 100 may also act as an AR eyewear glass. In some embodiments, near-eye display 100 augments views of a physical, real-world environment, with computer-generated elements (e.g., images, video, sound).

Near-eye display 100 includes waveguide display assembly 210, one or more position sensors 525, and/or an inertial measurement unit (IMU) 530. Waveguide display assembly 210 includes source assembly 310, output waveguide 320, and controller 330.

IMU 530 is an electronic device that generates fast calibration data indicating an estimated position of near-eye display 100 relative to an initial position of near-eye display 100 based on measurement signals received from one or more of position sensors 525.

Imaging device 535 may generate image data for various applications. For example, imaging device 535 may generate image data to provide slow calibration data in accordance with calibration parameters received from control circuitries 510. Imaging device 535 may include, for example, image sensors 120a 120d of FIG. 1A for generating image data of a physical environment in which the user is located for performing location tracking of the user. Imaging device 535 may further include, for example, image sensors 150a 150b of FIG. 1B for generating image data for determining a gaze point of the user to identify an object of interest of the user.

The input/output interface 540 is a device that allows a user to send action requests to the control circuitries 510. An action request is a request to perform a particular action. For example, an action request may be to start or end an application or to perform a particular action within the application.

Control circuitries 510 provide media to near-eye display 100 for presentation to the user in accordance with information received from one or more of: imaging device 535, near-eye display 100, and input/output interface 540. In some examples, control circuitries 510 can be housed within system 500 configured as a head-mounted device. In some examples, control circuitries 510 can be a standalone console device communicatively coupled with other components of system 500. In the example shown in FIG. 5, control circuitries 510 include an application store 545, a tracking module 550, and an engine 555.

The application store 545 stores one or more applications for execution by the control circuitries 510. An application is a group of instructions that when executed by a processor generates content for presentation to the user. Examples of applications include: gaming applications, conferencing applications, video playback applications, or other suitable applications.

Tracking module 550 calibrates system 500 using one or more calibration parameters and may adjust one or more calibration parameters to reduce error in determination of the position of the near-eye display 100.

Tracking module 550 tracks movements of near-eye display 100 using slow calibration information from the imaging device 535. Tracking module 550 also determines positions of a reference point of near-eye display 100 using position information from the fast calibration information.

Engine 555 executes applications within system 500 and receives position information, acceleration information, velocity information, and/or predicted future positions of near-eye display 100 from tracking module 550. In some embodiments, information received by engine 555 may be used for producing a signal (e.g., display instructions) to waveguide display assembly 210 that determines a type of content presented to the user. For example, to provide an interactive experience, engine 555 may determine the content to be presented to the user based on a location of the user (e.g., provided by tracking module 550), or a gaze point of the user (e.g., based on image data provided by imaging device 535), a distance between an object and user (e.g., based on image data provided by imaging device 535).

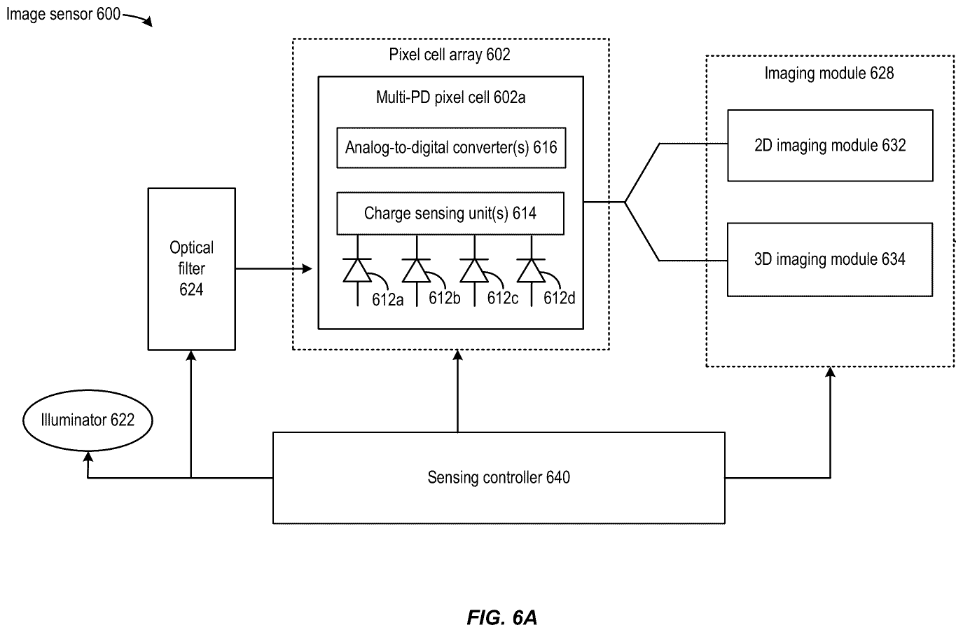

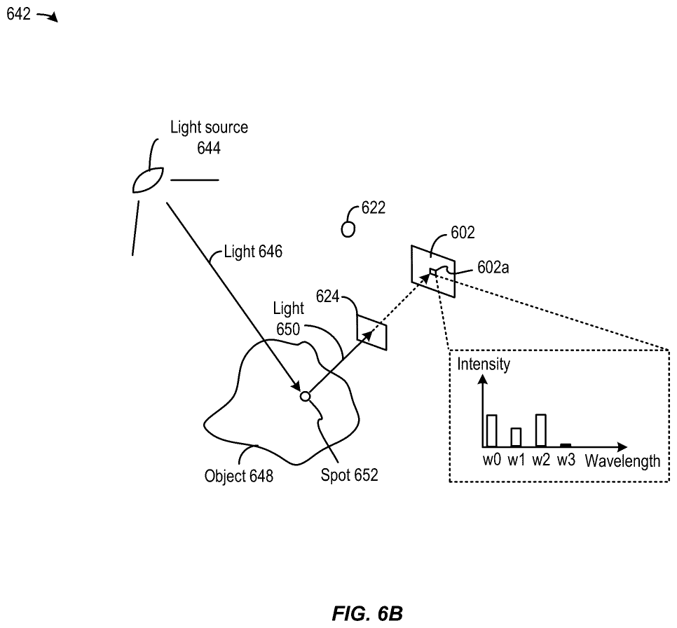

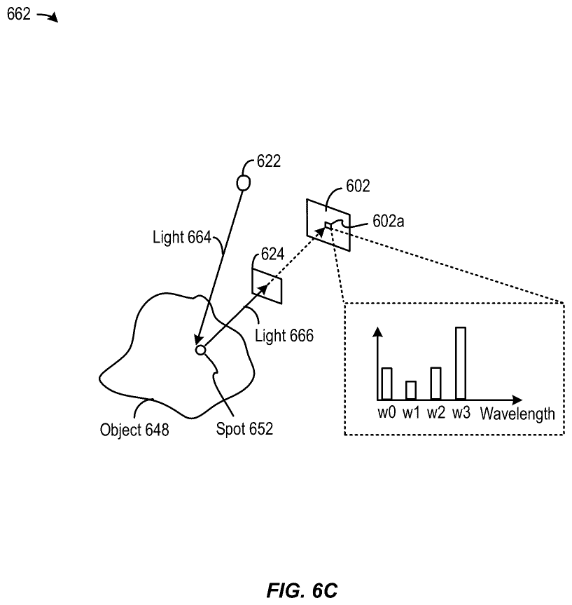

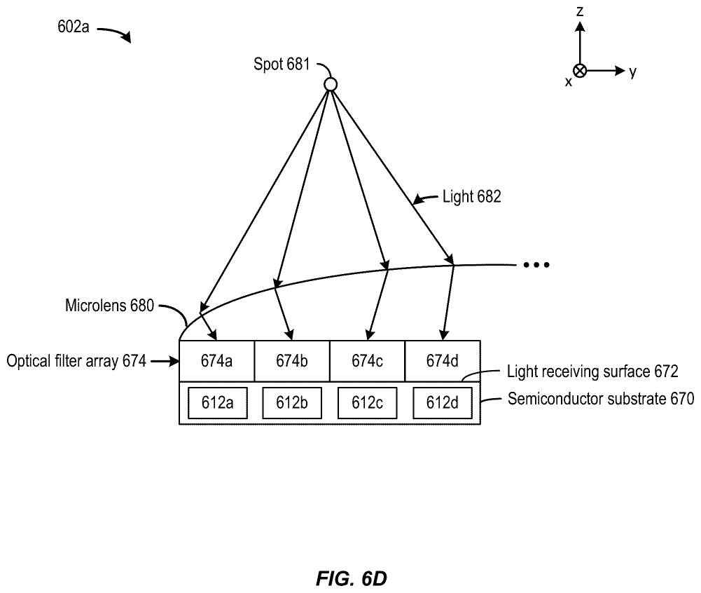

FIG. 6A-FIG. 6D illustrates an example of an image sensor 600 and its operations. Image sensor 600 can be part of near-eye display 100, and can provide 2D and 3D image data to control circuitries 510 of FIG. 5 to control the display content of near-eye display 100. As shown in FIG. 6A, image sensor 600 may include an pixel cell array 602, including pixel cell 602a. Pixel cell 602a can include a plurality of photodiodes 612 including, for example, photodiodes 612a, 612b, 612c, and 612d, one or more charge sensing units 614, and one or more quantizers/analog-to-digital converters 616. The plurality of photodiodes 612 can convert different components of incident light to charge. For example, photodiode 612a-612c can correspond to different visible light channels, in which photodiode 612a can convert a visible blue component (e.g., a wavelength range of 450-490 nanometers (nm)) to charge. Photodiode 612b can convert a visible green component (e.g., a wavelength range of 520-560 nm) to charge. Photodiode 612c can convert a visible red component (e.g., a wavelength range of 635-700 nm) to charge. Moreover, photodiode 612d can convert an infrared component (e.g., 700-1000 nm) to charge. Each of the one or more charge sensing units 614 can include a charge storage device and a buffer to convert the charge generated by photodiodes 612a-612d to voltages, which can be quantized by one or more ADCs 616 into digital values. The digital values generated from photodiodes 612a-612c can represent the different visible light components of a pixel, and each can be used for 2D sensing in a particular visible light channel. Moreover, the digital value generated from photodiode 612d can represent the IR light component of the same pixel and can be used for 3D sensing. Although FIG. 6A shows that pixel cell 602a includes four photodiodes, it is understood that the pixel cell can include a different number of photodiodes (e.g., two, three).

In some examples, image sensor 600 may also include an illuminator 622, an optical filter 624, an imaging module 628, and a sensing controller 640. Illuminator 622 may be an IR illuminator, such as a laser or a light emitting diode (LED), that can project IR light for 3D sensing. The projected light may include, for example, structured light or light pulses. Optical filter 624 may include an array of filter elements overlaid on the plurality of photodiodes 612a-612d of each pixel cell including pixel cell 602a. Each filter element can set a wavelength range of incident light received by each photodiode of pixel cell 602a. For example, a filter element over photodiode 612a may transmit the visible blue light component while blocking other components, a filter element over photodiode 612b may transmit the visible green light component, a filter element over photodiode 612c may transmit the visible red light component, whereas a filter element over photodiode 612d may transmit the IR light component.

Image sensor 600 further includes an imaging module 628. Imaging module 628 may further include a 2D imaging module 632 to perform 2D imaging operations and a 3D imaging module 634 to perform 3D imaging operations. The operations can be based on digital values provided by ADCs 616. For example, based on the digital values from each of photodiodes 612a-612c, 2D imaging module 632 can generate an array of pixel values representing an intensity of an incident light component for each visible color channel, and generate an image frame for each visible color channel. Moreover, 3D imaging module 634 can generate a 3D image based on the digital values from photodiode 612d. In some examples, based on the digital values, 3D imaging module 634 can detect a pattern of structured light reflected by a surface of an object, and compare the detected pattern with the pattern of structured light projected by illuminator 622 to determine the depths of different points of the surface with respect to the pixel cells array. For detection of the pattern of reflected light, 3D imaging module 634 can generate pixel values based on intensities of IR light received at the pixel cells. As another example, 3D imaging module 634 can generate pixel values based on time-of-flight of the IR light transmitted by illuminator 622 and reflected by the object.

Image sensor 600 further includes a sensing controller 640 to control different components of image sensor 600 to perform 2D and 3D imaging of an object. FIG. 6B and FIG. 6C illustrate examples of operations of image sensor 600 for 2D and 3D imaging. FIG. 6B illustrates an example of operation 642 for 2D imaging. For 2D imaging, pixel cells array 602 can detect visible light in the environment, including visible light reflected off an object. For example, referring to FIG. 6B, visible light source 644 (e.g., a light bulb, the sun, or other sources of ambient visible light) can project visible light 646 onto an object 648. Visible light 650 can be reflected off a spot 652 of object 648. Visible light 650 can also include the ambient IR light component. Visible light 650 can be filtered by optical filter array 624 to pass different components of visible light 650 of wavelength ranges w0, w1, w2, and w3 to, respectively, photodiodes 612a, 612b, 612c, and 612d of pixel cell 602a. Wavelength ranges w0, w1, w2, and w3 can correspond to, respectively, blue, green, red, and IR. As shown in FIG. 6B, as the IR illuminator 622 is not turned on, the intensity of IR component (w3) is contributed by the ambient IR light and can be very low. Moreover, different visible components of visible light f can also have different intensities. Charge sensing units 614 can convert the charge generated by the photodiodes to voltages, which can be quantized by ADCs 616 into digital values representing the red, blue, and green components of a pixel representing spot 652.

FIG. 6C illustrates an example of operation 662 for 3D imaging. Furthermore, image sensor 600 can also perform 3D imaging of object 648. Referring to FIG. 6C, sensing controller 610 can control illuminator 622 to project IR light 664, which can include a light pulse, structured light, etc., onto object 648. IR light 664 can have a wavelength range of 700 nanometers (nm) to 1 millimeter (mm). IR light 666 can reflect off spot 652 of object 648 and can propagate towards pixel cells array 602 and pass through optical filter 624, which can provide the IR component (of wavelength range w3) to photodiode 612d to convert to charge. Charge sensing units 614 can convert the charge to a voltage, which can be quantized by ADCs 616 into digital values.

FIG. 6D illustrates an example of arrangements of photodiodes 612 as well as optical filter 624. As shown in FIG. 6D, the plurality of photodiodes 612 can be formed within a semiconductor substrate 670 having a light receiving surface 672, and the photodiodes can be arranged laterally and parallel with light receiving surface 672. As shown in FIG. 6D, with light receiving surface 672 being parallel with the x and y axes, photodiodes 612a, 612b, 612c, and 612d can be arranged adjacent to each other also along the x and y axes in semiconductor substrate 670. Pixel cell 602a further includes an optical filter array 674 overlaid on the photodiodes. Optical filter array 674 can be part of optical filter 624. Optical filter array 860 can include a filter element overlaid on each of photodiodes 612a, 612b, 612c, and 612d to set a wavelength range of incident light component received by the respective photodiode. For example, filter element 674a is overlaid on photodiode 612a and can allow only visible blue light to enter photodiode 612a. Moreover, filter element 674b is overlaid on photodiode 612b and can allow only visible green light to enter photodiode 612b. Further, filter element 674c is overlaid on photodiode 612c and can allow only visible red light to enter photodiode 612c. Filter element 674d is overlaid on photodiode 612d and can allow only IR light to enter photodiode 612d. Pixel cell 602a further includes one or more microlens(es) 680, which can project light 682 from a spot of a scene (e.g., spot 681) via optical filter array 674 to different lateral locations of light receiving surface 672, which allows each photodiode to become a sub-pixel of pixel cell 602a and to receive components of light from the same spot corresponding to a pixel. In some examples, pixel cell 602a can also include multiple microlenses 680, with each microlens 680 positioned over a photodiode 612.

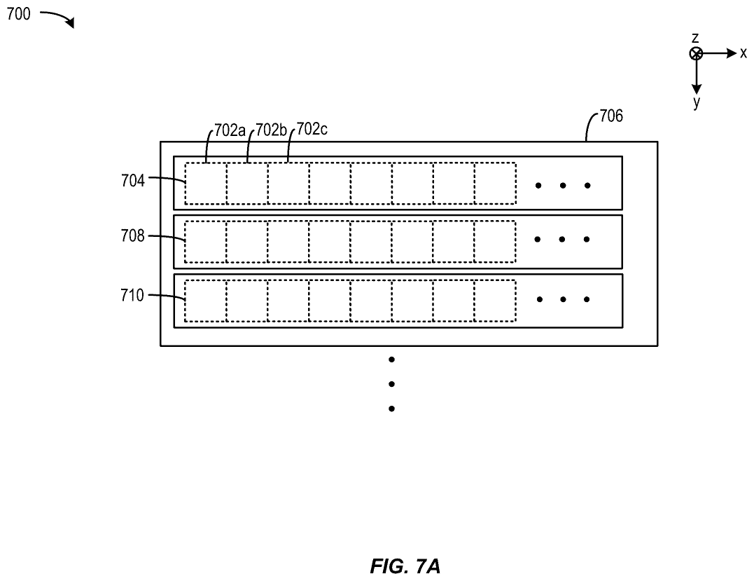

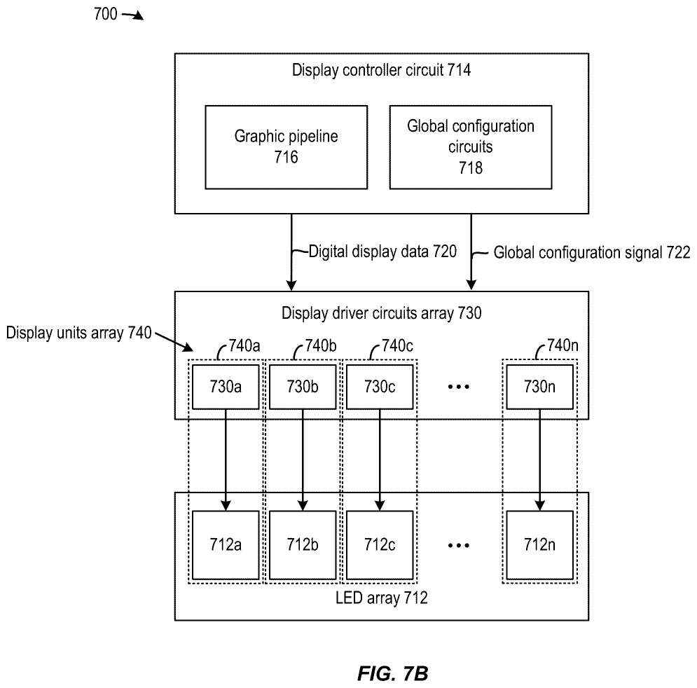

FIG. 7A, FIG. 7B, and FIG. 7C illustrates examples of a display 700. Display 700 can be part of display 110 of FIG. 2 and part of near-eye display 100 of FIG. 1A-1B. As shown in FIG. 7A, display 700 can include an array of display elements such as display element 702a, 702b, 702c, etc. Each display element can include, for example, a light emitting diode (LED), which can emit light of a certain color and of a particular intensity. Examples of LED can include Inorganic LED (ILED) and Organic LED (OLED). A type of ILED is MicroLED (also known as μLED and uLED). A “μLED,” “uLED,” or “MicroLED,” described herein refers to a particular type of ILED having a small active light emitting area (e.g., less than 2,000 μm2) and, in some examples, being capable of generating directional light to increase the brightness level of light emitted from the small active light emitting area. In some examples, a micro-LED may refer to an LED that has an active light emitting area that is less than 50 μm, less than 20 μm, or less than 10 μm. In some examples, the linear dimension may be as small as 2 μm or 4 μm. In some examples, the linear dimension may be smaller than 2 μm. For the rest of the disclosure, “LED” may refer μLED, ILED, OLED, or any type of LED devices.

In some examples, display 700 can be configured as a scanning display in which the LEDs configured to emit light of a particular color are formed as a strip (or multiple strips). For example, display elements/LEDs 702a, 702b, 702c can be assembled to form a strip 704 on a semiconductor substrate 706 to emit green light. In addition, strip 708 can be configured to emit red light, whereas strip 710 can be configured to emit blue light.

FIG. 7B illustrate examples of additional components of a display 700. As shown in FIG. 7B, display 700 can include an LED array 712 including, for example, LED 712a, 712b, 712c, 712n, etc., which can form strips 704, 708, 710 of FIG. 7A. LED array 712 may include an array of individually-controllable LEDs. Each LED can be configured to output visible light of pre-determined wavelength ranges (e.g., corresponding to one of red, green, or blue) at a pre-determined intensity. In some examples, each LED can form a pixel. In some examples, a group of LEDs that output red, green, and blue lights can have their output lights combined to also form a pixel, with the color of each pixel determined based on the relative intensities of the red, green, and blue lights (or lights of other colors) output by the LEDs within the group. In such a case, each LED within a group can form a sub-pixel. Each LED of LED array 712 can be individually controlled to output light of different intensities to output an image comprising an array of pixels.

In addition, display 700 includes a display controller circuit 714, which can include graphic pipeline 716 and global configuration circuits 718, which can generate, respectively, digital display data 720 and global configuration signal 722 to control LED array 712 to output an image. Specifically, graphic pipeline 716 can receive instructions/data from, for example, a host device to generate digital pixel data for an image to be output by LED array 712. Graphic pipeline 716 can also map the pixels of the images to the groups of LEDs of LED array 712 and generate digital display data 720 based on the mapping and the pixel data. For example, for a pixel having a target color in the image, graphic pipeline 305 can identify the group of LEDs of LED array 712 corresponding that pixel, and generate digital display data 720 targeted at the group of LEDs. The digital display data 720 can be configured to scale a baseline output intensity of each LEDs within the group to set the relative output intensities of the LEDs within the group, such that the combined output light from the group can have the target color.

In addition, global configuration circuits 718 can control the baseline output intensity of the LEDs of LED array 302, to set the brightness of output of LED array 712. In some examples, global configuration circuits 718 can include a reference current generator as well as current mirror circuits to supply global configuration signal 722, such as a bias voltage, to set the baseline bias current of each LED of LED array 302.

Display 700 further includes a display driver circuits array 730, which includes digital and analog circuits to control LED array 712 based on digital display data 720 and global configuration signal 722. Display driver circuit array 730 may include a display driver circuit for each LED of LED array 712. The controlling can be based on supplying a scaled baseline bias current to each LED of LED array 712, with the baseline bias current set by global configuration signal 722, while the scaling can be set by digital display data 720 for each individual LED. For example, as shown in FIG. 7B, display driver circuit 730a controls LED 712a, display driver circuit 730b controls LED 712b, display driver circuit 730c controls LED 712c, display driver circuit 730n controls LED 712n, etc. Each pair of a display driver circuit and a LED can form a display unit which can correspond to a sub-pixel (e.g., when a group of LEDs combine to form a pixel) or a pixel (e.g., when each LED forms a pixel). For example, display driver circuit 730a and LED 712a can form a display unit 740a, display driver circuit 730b and LED 712b can form a display unit 740b, display driver circuit 730c and LED 712c can form a display unit 740c, display driver circuit 730n and LED 712n can form a display unit 740n, etc., and a display units array 740 can be formed. Each display unit of display units array 740 can be individually controlled by graphic pipeline 716 and global configuration circuits 718 based on digital display data 720 and global configuration signal 722.

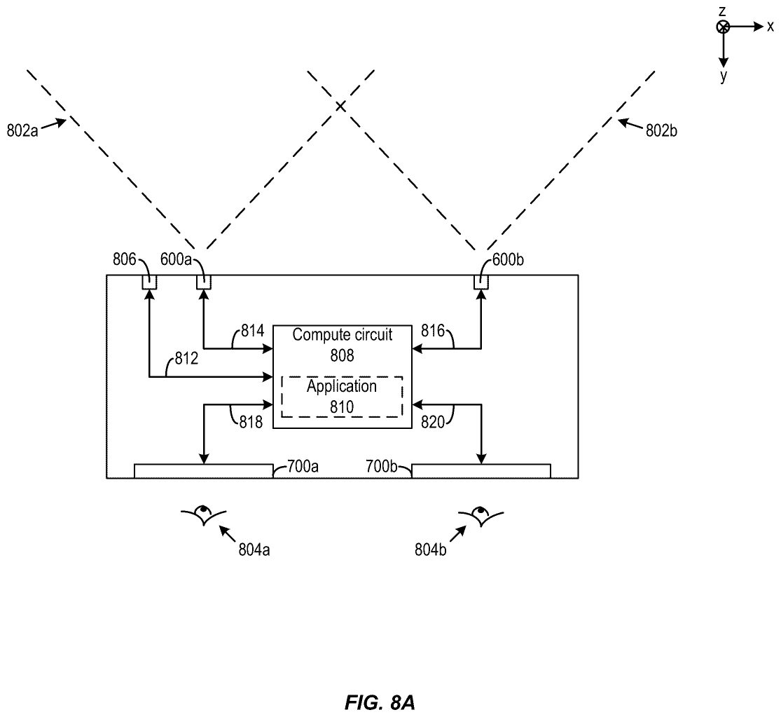

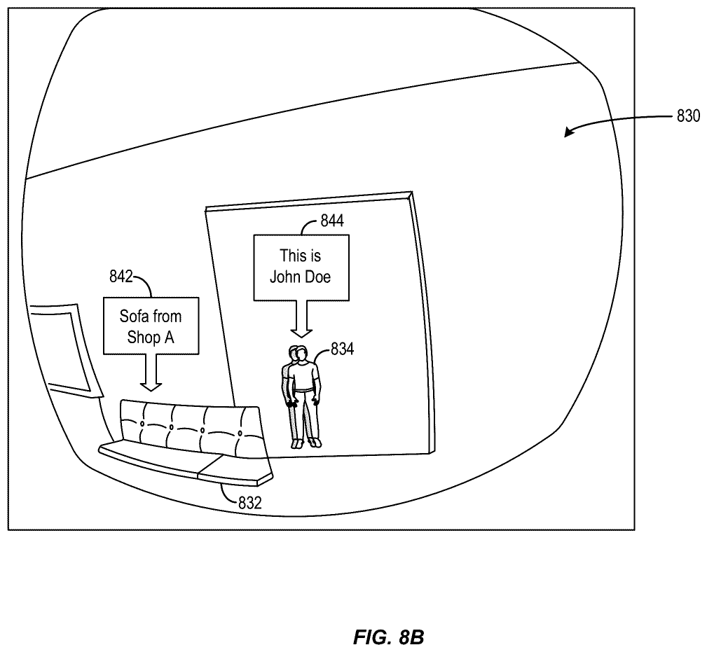

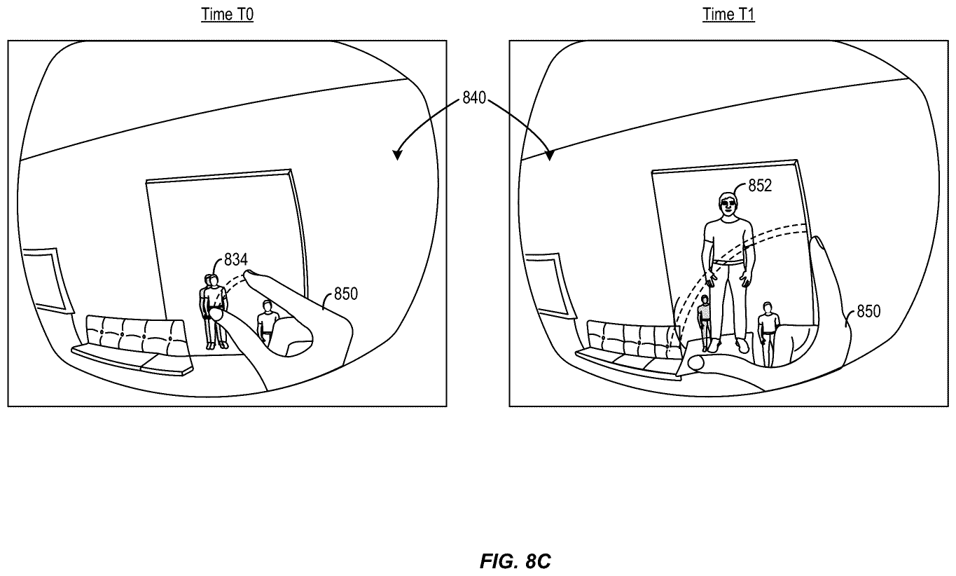

FIG. 8A, FIG. 8B, and FIG. 8C illustrates examples of a mobile device 800 and its operations. Mobile device 800 may include image sensor 600 of FIG. 6A-FIG. 6D and display 700 of FIG. 7A-FIG. 7B. Image sensor 600 can include an image sensor 600a to capture the field-of-view 802a of a left eye 804a of a user as well as an image sensor 600b to capture the field-of-view 802b of a right eye 804b of the user. Display 700 can include a left eye display 700a to output contents to left eye 804a of the user as well as a right eye 700b to output contents to right eye 804b of the user. Mobile device 800 may further include other types of sensors, such as a motion sensor 806 (e.g., an IMU). Each of image sensors 600a, 600b, motion sensor 806, and displays 700a and 700b can be in the form of discrete components. Mobile device may include a compute circuit 808 that operates an application 810 to receive sensor data from image sensors 600a and 600b and motion sensor 806, generates contents based on the sensor data, and outputs the contents via displays 700a and 700b. Compute circuit 808 can also include computation and memory resources to support the processing of the sensor data and generation of contents. Compute circuit 808 can be connected with motion sensor 806, image sensors 600a and 600b, and displays 700a and 700b via, respectively, buses 812, 814, 816, 818, and 820. Each bus can conform to the mobile industry processor interface (MIPI) specification.

One example of application 810 hosted by compute circuit 808 is a VR/MR/AR application, which can generate virtual content based on the sensor data of the mobile device to provide user a simulated experience of being in a virtual world, or in a hybrid world having a mixture of physical objects and virtual objects. To provide a VR/MR/AR experience, the application can determine various information, such as the orientation/pose of the user, location of the scene, physical objects present in a scene, etc., and generate contents based on the information. For example, the application can generate a virtual image representing a virtual scene to replace the physical scene the mobile device is in, and display the virtual image. The virtual image being displayed can be updated as the user moves or changes orientation/pose, the application can provide the user with a simulated experience of being immersed in a virtual world.

As another example, the application may generate a composite image including a part of the image of the physical scene as well as virtual contents, and display the composite image to the user, to provide AR/MR experiences. FIG. 8B illustrates an example of application 810 that provides AR/MR experience. As shown in FIG. 8B, mobile device 800 can capture an image of physical scene 830 via image sensors 600a and 600b. Application 810 can process the image and identify various objects of interest from the scene, such as sofa 832 and person 834. Application 810 can then generate annotations 842 and 844 about, respectively, sofa 832 and person 834. Application 810 can then replace some of the pixels of the image with the annotations as virtual contents to generate a composite image, and output the composite image via displays 700a and 700b. As the user moves within the physical scene while wearing mobile device 800, image sensors 600a and 600b can capture different images of the physical scene within the fields of view of the user, and the composite images output by displays 700a and 700b are also updated based on the captured images, which can provide a simulated experience of being immersed in a hybrid world having both physical and virtual objects.

FIG. 8C illustrates another example of application 810 that provides AR/MR experience. As shown in FIG. 8C, mobile device 800 can capture an image of physical scene 840, including a user's hand 850, via image sensors 600a and 600b. Application 810 can process the image and identify various objects of interest from the scene, including person 834 and user's hand 850 while outputting the image of physical scene 840 via displays 700a and 700b. Applicant 810 can also track the image of user's hand 850 to detect various hand gestures, and generate a composite image based on the detected gestures. For example, at time TO application 810 detects a first gesture of user's hand 850 which indicates selection of person 834. And then at time T1, upon detecting a second gesture of user's hand 850, application 810 can replace the original image of person 834 with a virtual object, such as a magnified image 852 of person 834, to generate a composite image, and output the composite image via displays 700a and 700b. By changing the output image based on detecting the user's hand gesture, application 810 can provide a simulated experience of being immersed in a hybrid world having both physical and virtual objects, and interacting with the physical/virtual objects.

The performance of application 810, as well as the immersive experience provided by the application, can be improved by increasing resolutions and operation speeds of image sensors 600a and 600b and displays 700a and 700b. By increasing the resolutions of the image sensors and the displays, more detailed images of the scene can be captured and (in the case of AR/MR) displayed to the user to provide improved simulation of vision. Moreover, in the case of VR, more detailed virtual scene can be constructed based on the captured images and displayed to user. Moreover, by increasing the operation speeds of the image sensor and the display, the images captured and displayed can change more responsively to changes in the location/orientation/pose of the user. All these can improve the user's simulated experience of being immersed in a virtual/hybrid world.

Although it is desirable to increase the resolutions and operation speeds of image sensors 600a and 600b and displays 700a and 700b, various constraints, such as area and power constraints imposed by mobile device 800, can limit the resolution and operation speeds of the image sensor and the displays. Specifically, due to the small form factors of mobile device 800, very limited space is available to fit in image sensors 600 and displays 700 and their support components (e.g., sensing controller 640, imaging module 628, display driver circuits array 720, display controller circuit 714, compute circuits 808), which in turn can limit the numbers of image sensing elements and display elements, as well as the quantities of available computation and memory resources, all of which can limit the achievable image sensing and display resolutions. The limited available power of mobile device 800 also constrains the numbers of image sensing elements and display elements.

In addition, operating the image sensor and the display at high frame rate requires moving a large quantity of image data and content data within the mobile device at a high data rate. But moving those data at a high data rate can involve massive compute resources and power consumption, especially when the data are moved over discrete electrical buses 812 820 within mobile device 800 over a considerable distance between compute circuits 808 and each of image sensors 600 and displays 700 at a high data rate. Due to the limited available power and computation resources at mobile device 800, the data rate for movement of image data and content data within the mobile device is also limited, which in turn can limit the achievable speeds of operation, as well as the achievable resolutions of the image sensor and the displays.

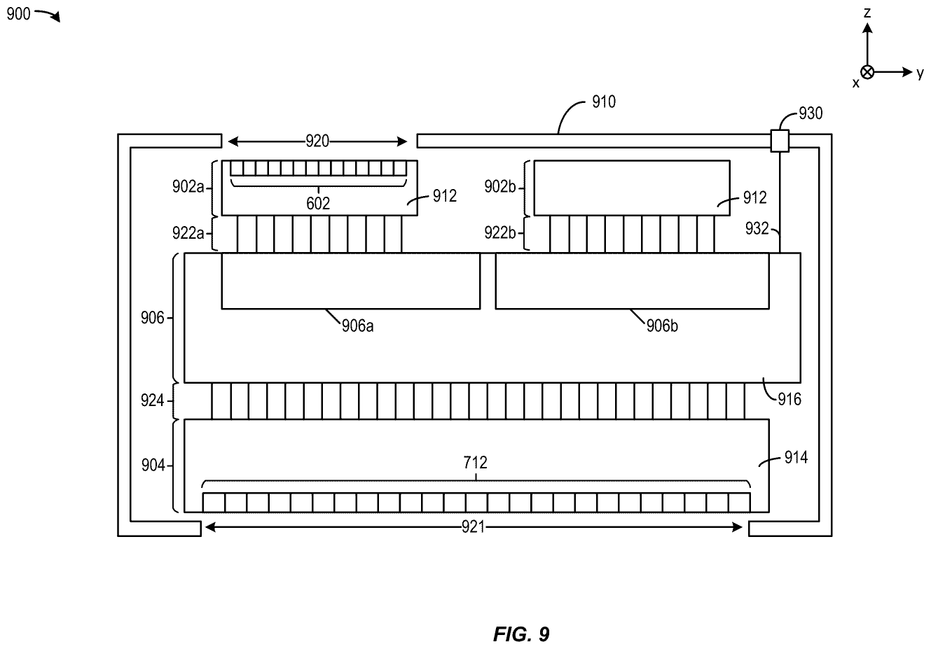

FIG. 9 illustrates an example of an integrated sensing and display system 900 that can address at least some of the issues above. Referring to FIG. 9, integrated system 900 may include one or more sensors 902, display 904, and compute circuits 906. Sensors 902 can include, for example, an image sensor 902a, a motion sensor (e.g., IMU) 902b, etc. Image sensor 902a can include components of image sensor 600 of FIG. 6A, such as pixel cell array 602. Display 904 can include components of display 700, such as LED array 712. Compute circuits 906 can receive sensor data from sensors 902a and 902b, generate content data based on the sensor data, and provide the content data to display 904 for displaying. Compute circuits 906 can include sensor compute circuits 906a to interface with sensors 902 and display compute circuits 906b to interface with display 904. Compute circuits 906a may include, for example, sensing controller 640 and imaging module 628 of FIG. 6A, whereas compute circuits 906b may include, for example, display controller circuit 714 of FIG. 7B. Compute circuits 906 may also include memory devices (not shown in FIG. 9) configured as buffers to support the sensing operations by sensors 902 and the display operations by display 904.

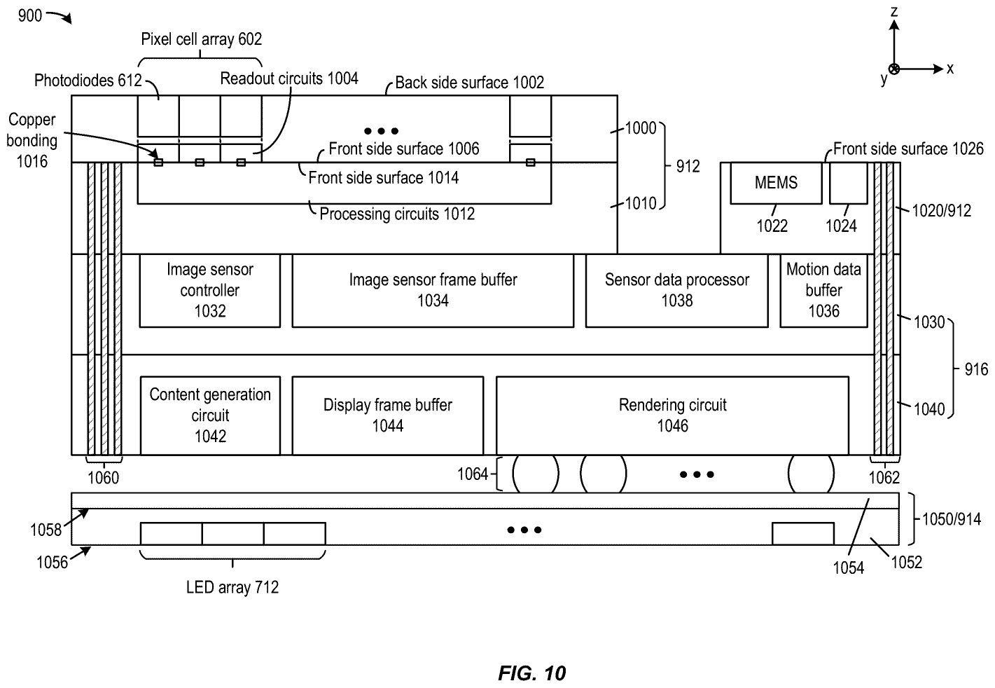

Sensors 902, display 904, and compute circuits 906 can be formed in different semiconductor layers which can be stacked. Each semiconductor layer can include one or more semiconductor substrates/wafers that can also be stacked to form the layer. For example, image sensor 902a and IMU 902b can be formed on a semiconductor layer 912, display 904 can be formed on a semiconductor layer 914, whereas compute circuits 906 can be formed on a semiconductor layer 916. Semiconductor layer 916 can be sandwiched between semiconductor layer 912 and semiconductor layer 914 (e.g., along the z-axis) to form a stack structure. In the example of FIG. 9, compute circuits 906a and 906b can be formed, for example, on a top side and a bottom side of a semiconductor substrate, or on the top sides of two semiconductor substrates forming a stack, as to be shown in FIG. 10, with the top sides of the two semiconductor substrates facing away from each other.

The stack structure of semiconductor layers 912, 914, and 916 can be enclosed at least partially within a semiconductor package 910 to form an integrated system. Semiconductor package 910 can be positioned within a mobile device, such as mobile device 800. Semiconductor package 910 can have an opening 920 to expose pixel cell array 602 and an opening 921 to expose LED array 712. Semiconductor package 910 further includes input/output (I/O) pins 930, which can be electrically connected to compute circuits 906 on semiconductor layer 916, to provide connection between integrated system 900 and other components of the mobile device, such as a host processor that executes a VR/AR/MR application, power system, etc. I/O pins 930 can be connected to, for example, semiconductor layer 916 via bond wires 932.

Integrated system 900 further includes interconnects to connect between the semiconductor substrates. For example, image sensor 902a of semiconductor layer 912 connected to semiconductor layer 916 via interconnects 922a to enable movement of data between image sensor 902a and sensor compute circuits 906a, whereas IMU 902b of semiconductor layer 912 is connected to semiconductor layer 916 via interconnects 922b to enable movement of data between IMU 902b and sensor compute circuits 906a. In addition, semiconductor layer 916 is connected to semiconductor layer 914 via interconnects 924 to enable movement of data between display compute circuits 906b and display 904. As to be described below, various techniques can be used to implement the interconnects, which can be implemented as 3D interconnects such as through silicon vias (TSVs), micro-TSVs, Copper-Copper bumps, etc. and/or 2.5D interconnects such as interposer.

FIG. 10 illustrates examples of internal components of semiconductor layers 912, 914, and 916 of integrated sensing and display system 900. As shown in FIG. 10, semiconductor layer 912 can include a semiconductor substrate 1000 and a semiconductor substrate 1010 forming a stack along a vertical direction (e.g., represented by z-axis) to form image sensor 902a. Semiconductor substrate 1000 can include photodiodes 612 of pixel cell array 602 formed on a back side surface 1002 of semiconductor substrate 1000, with back side surface 1002 becoming a light receiving surface of pixel cell array 602. Moreover, readout circuits 1004 (e.g., charge storage buffers, transfer transistors) can be formed on a front sides surface 1006 of semiconductor substrate 1000. Semiconductor substrate 1000 can include various materials such as Silicon, Germanium, etc., depending on the sensing wavelength.

In addition, semiconductor substrate 1010 can include processing circuits 1012 formed on a front side surface 1014. Processing circuits 1012 can include, for example, analog-to-digital converters (ADC) to quantize the charge generated by photodiodes 612 of pixel cell array 602, memory devices to store the outputs of the ADC, etc. Other components, such as metal capacitors or device capacitors, can also be formed on front side surface 1014 and sandwiched between semiconductor substrates 1000 and 1010 to provide additional charge storage buffers to support the quantization operations.

Semiconductor substrates 1000 and 1010 can be connected with vertical 3D interconnects, such as Copper bonding 1016 between front side surface 1006 of semiconductor substrate 1000 and front side surface 1014 of semiconductor substrate 1010, to provide electrical connections between the photodiodes and processing circuits. Such arrangements can reduce the routing distance of the pixel data from the photodiodes to the processing circuits.

In addition, integrated system 900 further includes a semiconductor substrate 1020 to implement IMU 902b. Semiconductor substrate 1020 can include a MEMS 1022 and a MEMS controller 1024 formed on a front side surface 1026 of semiconductor substrate 1020. MEMS 1022 and MEMS controller 1024 can form an IMU, with MEMS controller 1024 controlling the operations of MEMS 1022 and generating sensor data from MEMS 1022.

Moreover, semiconductor layer 916, which implements sensor compute circuits 906a and display compute circuits 906b, can include a semiconductor substrate 1030 and a semiconductor substrate 1040 forming a stack. Semiconductor substrate 1030 can implement sensor compute circuits 906a to interface with image sensor 902a and IMU 902b. Sensor compute circuits 906a can include, for example, an image sensor controller 1032, an image sensor frame buffer 1036, a motion data buffer 1036, and a sensor data processor 1038. Image sensor controller 1032 can control the sensing operations performed by the image sensor by, for example, providing global signals (e.g., clock signals, various control signals) to the image sensor. Image sensor controller 1032 can also enable a subset of pixel cells of pixel cell array 602 to generate a sparse image frame. In addition, image sensor frame buffer 1034 can store one or more image frames generated by pixel cell array 602, whereas motion data buffer 1036 can store motion measurement data (e.g., pitch, roll, yaw) measured by the IMU.

Sensor data processor 1038 can process the image frames stored in image sensor frame buffer 1034 and motion measurement data stored in motion data buffer 1036 to generate a processing result. For example, sensor data processor 1038 can include an image processor to process the image frames to determine the location and the size of a region of interest (ROI) enclosing a target object. The target object can be defined by the application on the host processor, which can send the target object information to the system. In addition, sensor data processor 1038 can include circuits such as, for example, a Kalman filter, to determine a state of motion, such as a location, an orientation, etc., of mobile device 800 based on the motion measurement data. Based on the image processing results and state of motion, image sensor controller 1032 can predict the location of the ROI for the next image frame, and enable a subset of pixel cells of pixel cell array 602 corresponding to the ROI to generate a subsequent sparse image frame. The generation of a sparse image frame can reduce the power consumption of the image sensing operation as well as the volume of pixel data transmitted by pixel cell array 602 to sensor compute circuits 906a. In addition, sensor data processor 1038 can also transmit the image processing and motion data processing results to sensor compute circuits 906b for display 904.

In addition, semiconductor substrate 1040 can implement display compute circuits 906b to interface with display 904 of semiconductor layer 914. Display compute circuits 906b can include, for example, a content generation circuit 1042, a display frame buffer 1044, and a rendering circuit 1046. Specifically, content generation circuit 1042 can receive a reference image frame, which can be a virtual image frame received externally from, for example, a host processor via I/O pins 930, or a physical image frame received from image sensor frame buffer 1034. Content generation circuit 1042 can generate an output image frame based on the reference image frame as well as the image processing and motion data processing results.

Specifically, in a case where the virtual image frame is received from the host processor, the content generation circuit can perform a transformation operation on the virtual image frame to reflect a change in the user's viewpoint based on the location and/or orientation information from the motion data processing results, to provide user a simulated experience of being in a virtual world. As another example, in a case where a physical image frame is received from the image processor, content generation circuit 1042 can generate the output image frame as a composite image based on adding virtual content such as, for example, replacing a physical object in the physical image frame with a virtual object, adding virtual annotations to the physical frame, etc., as described in FIG. 8A and FIG. 8B, to provide user a simulated experience of being in a hybrid world. Content generation circuit 1042 can also perform additional post-processing of the output image frame to, for example, compensate for optical and motion warping effects.

Content generation circuit 1042 can store the output image frame at display frame buffer 1044. Rendering circuit 1046 can include display driver circuits array 730 as well as control logic circuits. The control logic circuits can read pixels of the output image frame from display frame buffer 1044 according to a scanning pattern, and transmit control signals to display driver circuits array 730, which can then control LED array 712 to display the output image frame.

Semiconductor substrates 1010 (of semiconductor layer 912), as well as semiconductor substrates 1030 and 1040 (of semiconductor layer 916), can include digital logics and memory cells. Semiconductor substrates 1010, 1030, and 1040 may include silicon transistor devices, such as FinFET, GAAFET, etc., to implement the digital logics, as well as memory devices, such as MRAM device, ReRAM device, SRAM devices, etc., to implement the memory cells. The semiconductor substrates may also include other transistor devices, such as analog transistors, capacitors, etc., to implement analog circuits, such as analog-to-digital converter (ADC) to quantize the sensor signals, display driver circuits to transmit current to LED array 712, etc.

In some examples, semiconductor layer 914, which implements LED array 712, can include a semiconductor substrate 1050 which includes a device layer 1052, and a thin-film circuit layer 1054 deposited on device layer 1052. LED array 712 can be formed in a layered epitaxial structure include a first doped semiconductor layer (e.g., a p-doped layer), a second doped semiconductor layer (e.g., an n-doped layer), and a light-emitting layer (e.g., an active region). Device layer 1052 has a light emitting surface 1056 facing away from the light receiving surface of pixel cell array 602, and an opposite surface 1058 that is opposite to light emitting surface 1056.

Thin-film circuit layer 1054 is deposited on the opposite surface 1056 of device layer 1052. Thin-film circuit layer 1054 can include a transistor layer (e.g., a thin-film transistor (TFT) layer); an interconnect layer; and/or a bonding layer (e.g., a layer comprising a plurality of pads for under-bump metallization). Device layer 1052 can provide a support structure for thin-film circuit layer 1054. Thin-film circuit layer 1054 can include circuitry for controlling operation of LEDs in the array of LEDs, such as circuitry that routes the current from display driver circuits to the LEDs. Thin-film circuit layer 1054 can include materials including, for example, c-axis aligned crystal indium-gallium-zinc oxide (CAAC-IGZO), amorphous indium gallium zinc oxide (a-IGZO), low-temperature polycrystalline silicon (LTPS), amorphous silicon (a-Si), etc.

Semiconductor substrates 1000, 1010, 1020, 1030, 1040, and 1050, of semiconductor layers 912, 914, and 916, can be connected via 3D interconnects, such as through silicon vias (TSVs), micro-TSVs, Copper-Copper bumps, etc. For example, as described above, semiconductor substrates 1000 and 1010 can be connected via Copper bonding 1016. In addition, semiconductor substrates 1010, 1030, and 1040 can be connected via through silicon vias 1060 (TSVs), which penetrate through the semiconductor substrates. Moreover, semiconductor substrates 1020, 1030, and 1040 can be connected via TSVs 1062, which penetrate through the semiconductor substrates. Further, semiconductor substrates 1040 and 1050 can be connected via a plurality of metal bumps, such as micro bumps 1064, which interface with thin-film circuit layer 1054.

In some examples, integrated sensing and display system 900 may further include a power management circuit (not shown in FIG. 10), which can be implemented in, for example, semiconductor substrates 1030 and/or 1040, or in other semiconductor substrates not shown in FIG. 10. The power management circuit may include, for example, bias generators, regulators, charge pumps/DC-DC converters to generate voltage for the entire system or part of it (e.g., MEMS 1020, pixel cell array 602, LED array 712, etc.

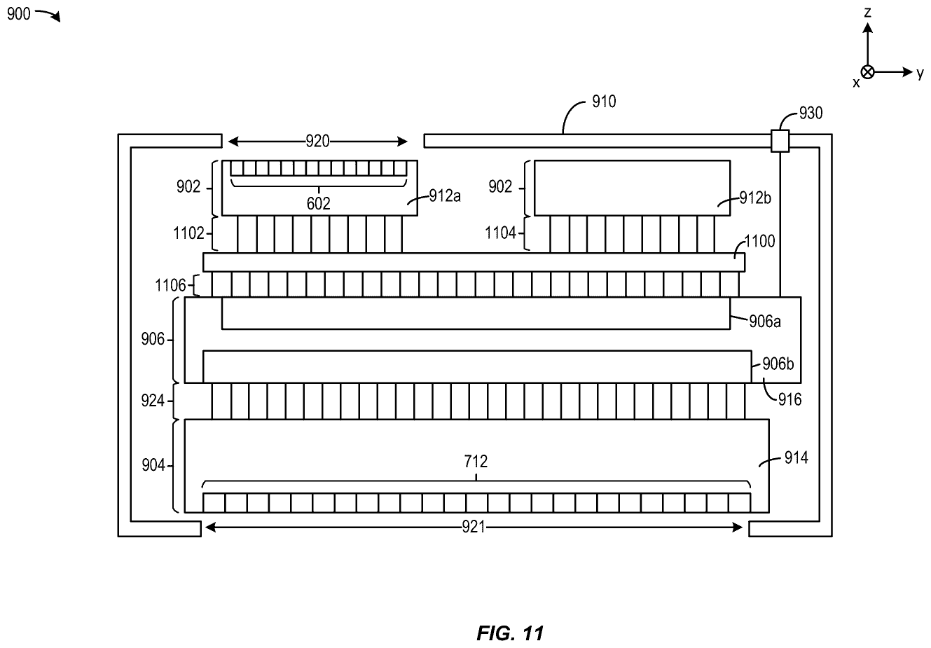

In some examples, at least some of semiconductor layers 912, 914, and 916 can be connected via 2.5D interconnects to form a multi-chip module (MCM). FIG. 11 illustrates examples of integrated system 900 having 2.5D interconnects. As shown in FIG. 11, image sensor 902a and IMU 902b can be implemented as chiplets. Both chiplets can be connected to an interposer 1100 via a plurality of bumps, such as micro bumps 1102 and 1104. Interposer 1100, in turn, can be connected to semiconductor layer 916 via a plurality of bumps, such as micro bumps 1106.

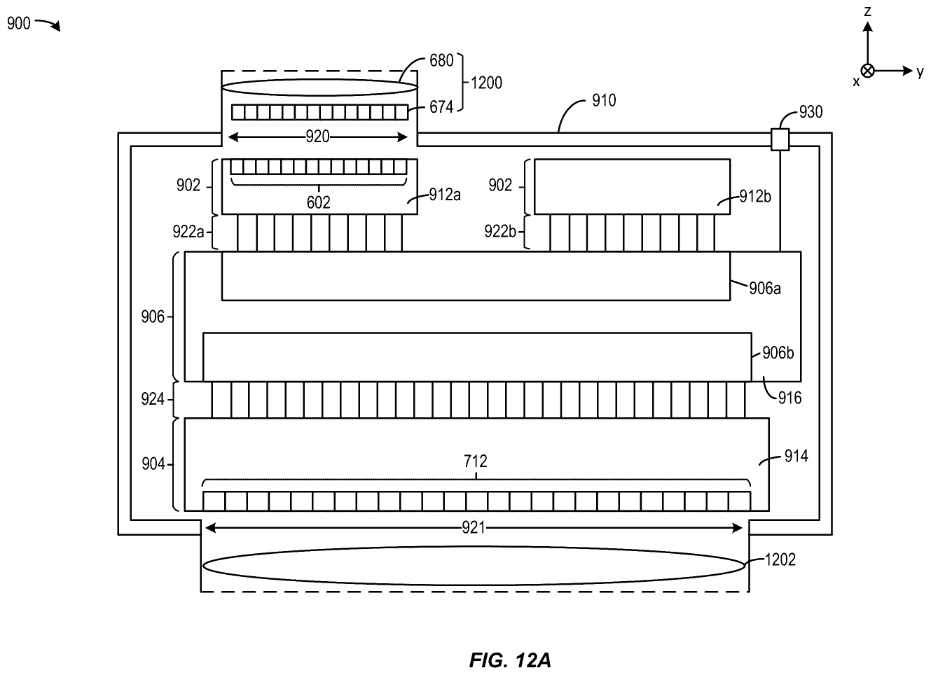

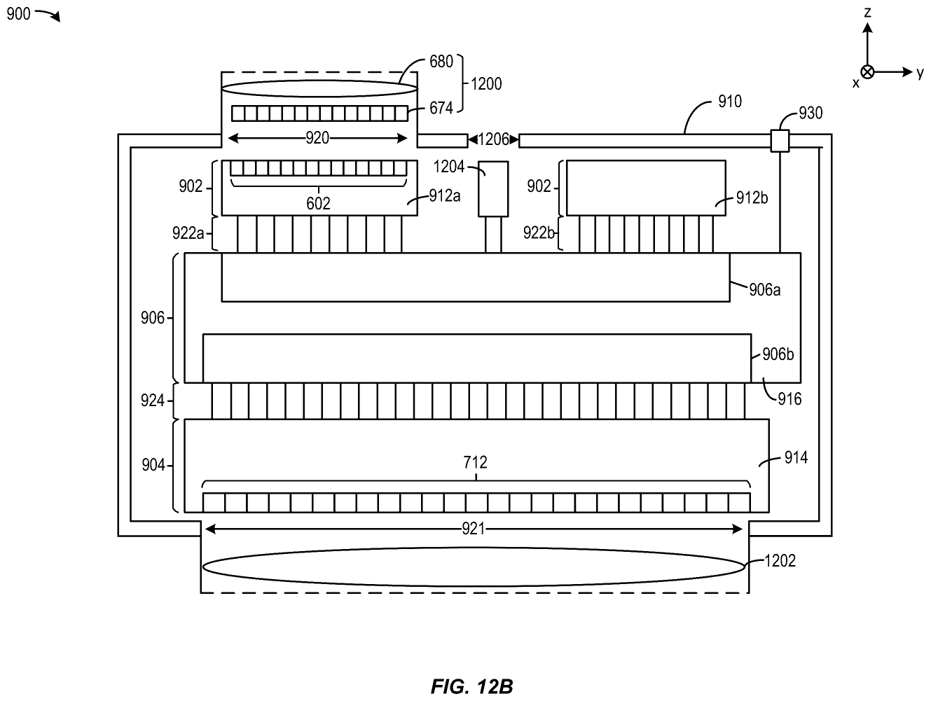

FIG. 12A and FIG. 12B illustrate additional components that can be included in integrated system 900 to support the VR/AR/MR application. For example, referring to FIG. 12A, integrated system 900 can include an optical stack 1200 including microlens 680 and filter array 674 of FIG. 6D positioned over opening 920 and image sensor 902a to project light from the same spot to different photodiodes within a pixel cell and to select a wavelength of the light to be detected by each photodiode. In addition, integrated system 900 can include a lens 1202 positioned over opening 921 and LED array 712 to control the optical properties (e.g., focus, distortion) of the light exiting the display. In some examples, microlens 680 and lens 1202 can include wafer level optics.

In addition, integrated system 900 may further include one or more illuminators for active sensing. For example, referring to FIG. 12B, the integrated system may include a laser diode 1204 (e.g., vertical-cavity surface-emitting lasers (VCSELs)) to project light to support a depth-sensing operation, such as the depth-sensing operation of FIG. 6C. Semiconductor package 910 can include an opening 1206 adjacent to opening 920 over image sensor 902a to expose laser diode 1204, which can be connected to semiconductor layer 916. Laser diode 1204 can project light (e.g., structured light) into the scene, and image sensor 902a can detect light reflected from the scene. As another example (not shown in the figures), integrated system 900 may include another light emitting diode (LED) adjacent to LED array 712 of display 904 to project light towards the user's eyes when the user watches the display. Images of the eyes can then be captured by the image sensor on the second surface to support, for example, eye tracking.

Referring back to FIG. 10, to generate an output image frame for display, compute circuits 906 may obtain a physical image frame from image sensor frame buffer 1034, store the physical image frame in display frame buffer 1044, and then replace some of the pixels in the physical image frame stored in display frame buffer 1044 to add in virtual contents (e.g., annotations and virtual objects as shown in FIG. 8B and FIG. 8C) to generate the output image frame. Such arrangements, however, can introduce substantial delay to the generation of the output image frame. Specifically, both image sensor frame buffer 1034 and display frame buffer 1044 needs to be accessed sequentially to read and write the pixels from or into the frame buffers. As a result, substantial time is needed to transfer the physical image frame from the image sensor to display frame buffer 1044.

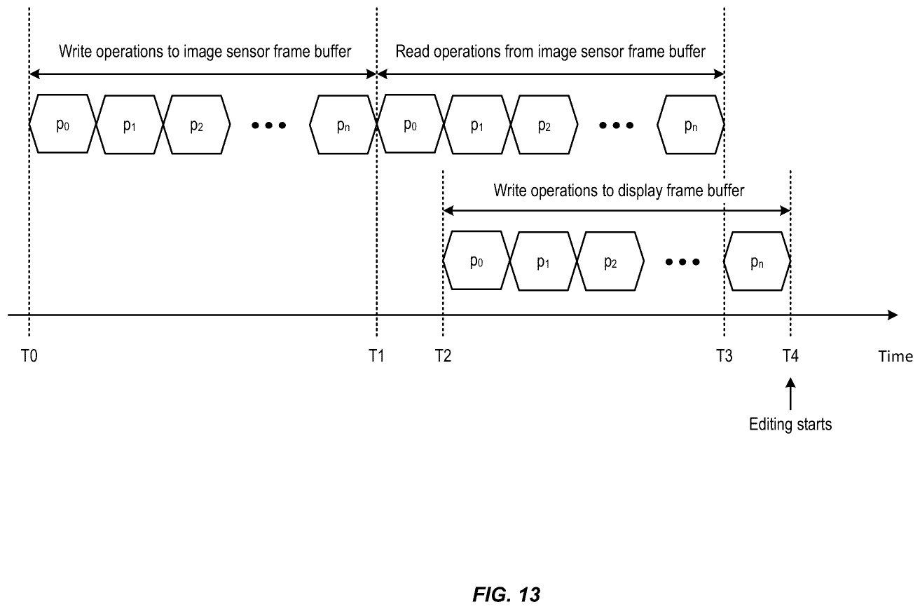

FIG. 13 illustrates an example timing diagram of operations to transfer a physical image frame from the image sensor to display frame buffer 1044. As shown in FIG. 13, image sensor frame buffer 1034 is sequentially accessed by image sensor 902a to write the pixel data of pixels (e.g., p0, p1, p2, pn, etc.) of the physical image frame into image sensor frame buffer 1034 between times T0 and T1. After the entire physical image frame is written into image sensor frame buffer 1034, content generation circuit 1042 can sequentially access image sensor frame buffer 1034 to read the pixels (between times T1 and T3), and sequentially access display frame buffer 1044 to store the pixels (between times T2 and T4). After the entire physical image frame is written into display frame buffer 1044, content generation circuit 1042 can start replacing pixels in display frame buffer 1044, at time T4. As a result, the generation of the composite/virtual image is delayed by a duration between times T0 and T4, which may increase with the resolution of the physical image frame. Despite the transfer of pixel data being substantially sped up by the 3D/2.5 interconnects, the delay incurred by the sequential accesses of image sensor frame buffer 1034 and display frame buffer 1044 can pose substantial limit on the speed of content generation by content generation circuit 1042.

To reduce the delay incurred by the memory access to content generation, in some examples, compute circuits 906 of integrated system 900 can include a shared frame buffer to be accessed by both sensor compute circuits 906a and display compute circuits 906b. Image sensor 902a can store a physical image frame at the shared frame buffer. Content generation circuit 1042 can read the physical image frame at the shared frame buffer and replace pixels of the image frame buffer to add in virtual contents to generate a composite image frame. Rendering circuit 1046 can then read the composite image frame from the shared frame buffer and output it to LED array 712. By taking away the time to store the input/output frame at the display frame buffer, the delay incurred by the sequential memory accesses can be reduced.

In some examples to further reduce the delay, a distributed sensing and display system can be implemented in which the display is divided into tiles of display elements and the image sensor is divided into tiles of image sensing elements. Each tile of display elements is directly connected to a corresponding tile memory in the third semiconductor substrate. Each tile memory is, in turn, connected to a corresponding tile of image sensing elements. Each tile memory can be accessed in parallel to store the physical image frame captured by the image sensor and to replace pixels to add in virtual contents. As each tile memory is typically small, the access time for each tile memory is relatively short, which can further reduce the delay incurred by memory access to content generation.

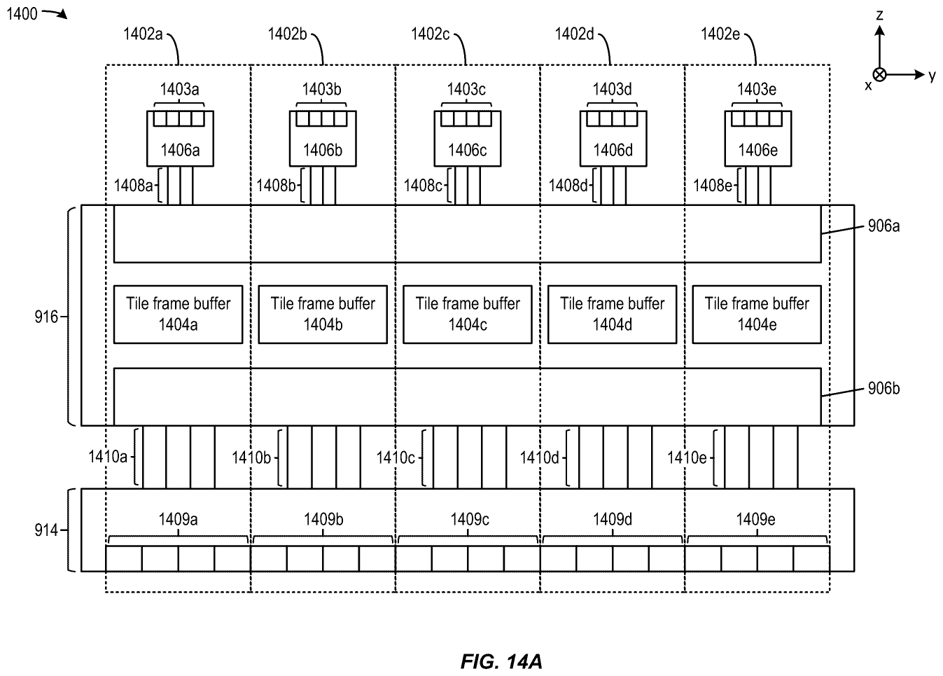

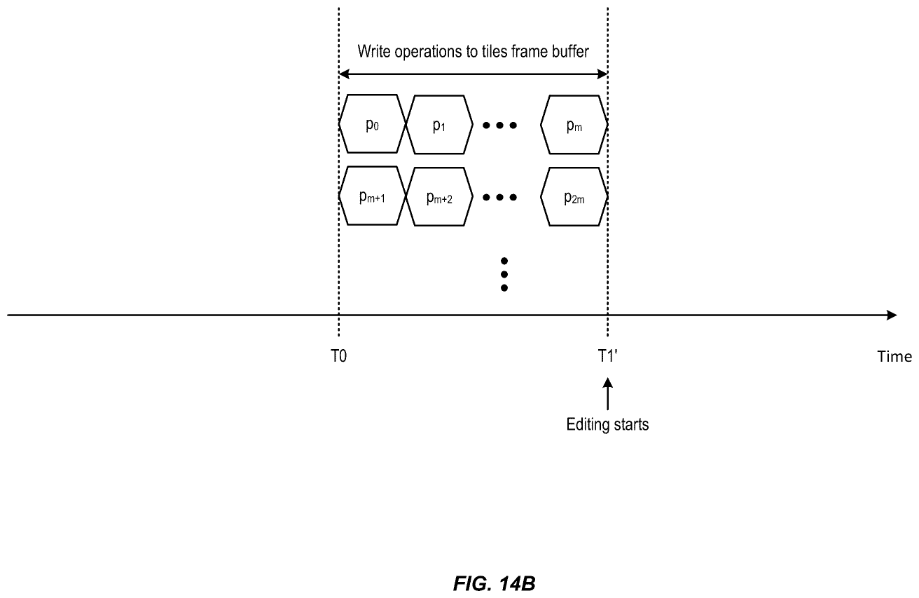

FIG. 14A illustrates an example of a distributed sensing and display system 1400. As shown in FIG. 14A, distributed sensing and display system 1400 can include a plurality of sensing and display units including, for example, units 1402a, 1402b, 1402c, 1402d, and 1402e. Each sensing and display unit 1402 includes an array of pixel cells, which can form a tile of image sensing elements. Each tile of image sensing elements can include a subset of pixel cells 602 and can be connected to a dedicated tile frame buffer 1404 in semiconductor layer 916, which in turn is connected to an array of LEDs. Each array of LEDs can form a tile of display elements and can be a subset of LED array 712. For example, sensing and display unit 1402a includes a semiconductor layer 1406a that implements an array of pixel cells 1403a, which forms a tile of image sensing elements is connected to a tile frame buffer 1404a via interconnects 1408a. Moreover, tile frame buffer 1404a is connected to an array of LEDs 1409a (in semiconductor layer 914) via interconnects 1410a. Likewise, sensing and display unit 1402b includes a tile frame buffer 1404b connected to an array of pixel cells 1403b (in semiconductor layer 1406b) and array of LEDs 1409b via, respectively, interconnects 1408b and 1410b. Moreover, sensing and display unit 1402c includes frame buffer 1404c connected to an array of pixel cells 1403c (in semiconductor layer 1406c) and an array of LED 1409c via, respectively, interconnects 1408c and 1410c. Further, sensing and display unit 1402d includes a tile frame buffer 1404d connected to an array of pixel cells 1403d (in semiconductor layer 1406d) and an array of LED 1409d via, respectively, interconnects 1408d and 1410d. In addition, sensing and display unit 1402e includes a tile frame buffer 1404e connected to an array of pixel cells 1403e (in semiconductor layer 1406e) and an array of LED 1409e via, respectively, interconnects 1408e and 1410e. Although FIG. 14A illustrates that different subsets of pixels are formed on different semiconductor layers, it is understood that the subsets of pixels can also be formed on the same semiconductor layer.

Each of tile frame buffers 1404a-1404e can be accessed in parallel by sensor compute circuits 906a to write subsets of pixels of a physical image frame captured by the corresponding array of pixel cells 1403. Each of tile frame buffers 1404a 1404e can also be accessed in parallel by display compute circuits 906b to replace pixels to add in virtual contents. The sharing of the frame buffer between sensor compute circuits 906a and display compute circuits 906b, as well as the parallel access of the tile frame buffers, can substantially reduce the delay incurred in the transfer of pixel data and speed up the generation of content.

FIG. 14B illustrates an example timing diagram of operations of distributed sensing and display system 1400. Referring to FIG. 14B, each tile frame buffer can be accessed in parallel to store pixel data from different subsets of pixel cells 602 between times T0 and T1′. For example, pixel data of pixels p0 to pm can be stored in tile frame buffer 1404a between times T0 and T1′, whereas pixel data of pixels pm+1 to p2m can be stored in tile frame buffer 1404b between the same times T0 and T1′. The entire physical image frame can be stored in the tile frame buffers at time T1′, at which point content generation circuit 1042 can start replacing pixels in the tile frame buffers. Compared with FIG. 13, the delay incurred by the sequential accesses of the frame buffers to store the physical image frame can be substantially reduced, which can substantially increase the speed of content generation by content generation circuit 1042.

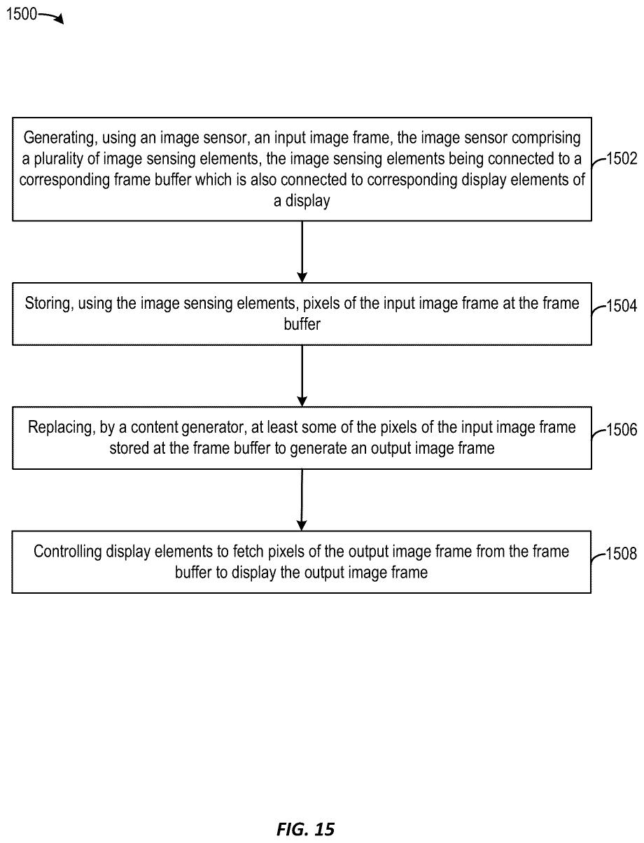

FIG. 15 illustrates a method 1500 of generating an output image frame. Method 1500 can be performed by, for example, distributed sensing and display system 1400.

Method 1500 starts with step 1502, in which an image sensor, such as image sensor including array of pixel cells 1403 (e.g., 1403a-e). Each array of pixel cells 1403 can form a tile of image sensing elements and connected to a corresponding tile frame buffer (e.g., one of tile frame buffers 1404a-e) which in turn is connected to a corresponding tile of display elements of a display (e.g., array of LEDs 1409a-e). The arrays of pixel cells 1403 can collectively capture light from a scene and generate an image frame of the scene.

It should be appreciated that while some examples may employ multiple tiles of image sensing elements, the method may employ an image sensor having a single array of pixel cells 1403 form a single tile of image sensing elements connected to a corresponding frame buffer.

In step 1504, each tile of image sensing elements can store a subset of pixels of the image frame at the corresponding tile frame buffer in parallel. For example, array of pixel cells 1403a can store a subset of pixels at tile frame buffer 1404a, array of pixel cells 1403b can store another subset of pixels at tile frame buffer 1404b, etc. The storage of the pixels at the respective tile frame buffer can be performed in parallel as each tile frame buffer is connected directly to the tile of image sensing element, as shown in FIG. 14B. In an example that employs only a single tile of image sensing elements, the image sensing elements store all pixels of the image frame within the frame buffer.

In step 1506, a content generator, such as content generation circuit 1042, can replace at least some of the pixels of the input image frame stored at the tile frame buffer(s) to generate the output image frame. In some examples, the pixels can be replaced to provide an annotation generated by sensor data processor 1038 based on, for example, detecting a target object in the input image frame, as shown in FIG. 9B. In some examples, the pixels being replaced can be based on an object detection operation by sensor data processor to, for example, replace a physical object with a virtual object, as shown in FIG. 9C.

In step 1508, a rendering circuit, such as rendering circuit 1046, can control each tile of display elements to fetch a subset of pixels of the output image frame from the corresponding tile frame buffer to display the output image frame. The rendering circuit can control the tiles of display elements based on a scanning pattern. Upon receiving a signal to output content, the tile of display elements can fetch the pixel data, which can include the pixel data of the original input frame or pixel data inserted by content generation circuit 1042, from the corresponding tile frame buffer and output the pixel data. If an image sensor with only a single tile of image sensing elements is employed, the rendering circuit controls the single frame buffer to display the output image frame.

With the disclosed techniques, an integrated system in which sensor, compute, and display are integrated within a semiconductor package can be provided. Such an integrated system can improve the performance of the sensor and the display while reducing the footprint and reducing power consumption. Specifically, by putting sensor, compute, and display within a semiconductor package, the distances travelled by the data between the sensor and the compute and between the compute and the display can be greatly reduced, which can improve the speed of transfer of data. The speed of data transfer can be further improved by the 2.5D and 3D interconnects, which can provide high-bandwidth and short-distance routes for the transfer of data. In addition, the integrated system also allows implementation of a distributed sensing and display system, which can further improve the system performance, as described above. All these allow the image sensor and the display to operate at a higher frame to improve their operation speeds. Moreover, as the sensor and the display are integrated within a rigid stack structure, relative movement between the sensor and the display (e.g., due to thermal expansion) can be reduced, which can reduce the need to calibrate the sensor and the display to account for the movement.

In addition, the integrated system can reduce the footprint and power consumption. Specifically, by stacking the compute circuits and the sensors on the back of the display, the overall footprint occupied by the sensors, the compute circuits, and the display can be reduced especially compared with a case where the display, the sensor, and the compute circuits are scattered at different locations. The stacking arrangements are also likely to achieve the minimum and optimum overall footprint, given that the displays typically have the largest footprint (compared with sensor and compute circuits), and that the image sensors need to be facing opposite directions from the display to provide simulated vision.

Moreover, in addition to improving the data transfer rate, the 2.5D/3D interconnects between the semiconductor substrates also allow the data to be transferred more efficiently compared with, for example, discrete buses such as those defined under the MIPI specification. For example, C-PHY Mobile Industry Processor Interface (MIPI) requires a few pico-Joule (pJ)/bit while wireless transmission through a 60 GHz link requires a few hundred pJ/bit. In contrast, due the high bandwidth and the short routing distance provided by the on-chip interconnects, the power consumed in the transfer of data over 2.5D/3D interconnects is typically just a fraction of pJ/bit. Furthermore, due to the higher transfer bandwidth and reduced transfer distance, the data transfer time can also be reduced as a result, which allows support circuit components (e.g., clocking circuits, signal transmitter and receiver circuits) to be powered off for a longer duration to further reduce the overall power consumption of the system.

An integrated sensing and display system, such as integrated system 900, can improve the performance of the sensor and the display while reducing the footprint and reducing power consumption. Specifically, by putting sensors 902, compute circuits 906, and display 904 within a single semiconductor package 910, rather than scattering them around at different locations within the mobile device, the distances travelled by the data between sensors 902 and compute circuits 906, and between compute circuits 906 and display 904, can be greatly reduced, which can improve the speed of transfer of data. The speed of data transfer can be further improved by the 2.5D/3D interconnects 922 and 924, which can provide high-bandwidth and short-distance routes for the transfer of data. All these allow image sensor 902a and display 904 to operate at a higher frame to improve their operation speeds.

Moreover, as sensors 902 and display 904 are integrated within a rigid stack structure, relative movement between sensors 902 and display 904 (e.g., due to thermal expansion) can be reduced. Compared with a case where the sensor and the display are mounted on separate printed circuit boards (PCBs) that are held together on non-rigid structures, integrated system 900 can reduce the relative movement between sensors 902 and display 904 which can accumulate over time. The reduced relative movement can be advantageous as the need to re-calibrate the sensor and the display to account for the movement can be reduced. Specifically, as described above, image sensors 600 can be positioned on mobile device 800 to capture images of a physical scene with the field-of-views (FOVs) of left and right eyes of a user, whereas displays 700 are positioned in front of the left and right eyes of the user to display the images of the physical scene, or virtual/composite images derived from the captured images, to simulate the vision of the user. If there are relative movements between the image sensors and the displays, the image sensors and/or the display may need to be calibrated (e.g., by post-processing the image frames prior to being displayed) to correct for the relative movements in order to simulate the vision of the user. By integrating the sensors and the display within a rigid stack structure, the relative movements between the sensors and the display can be reduced, which can reduce the need for the calibration.

In addition, integrated system 900 can reduce the footprint and power consumption. Specifically, by stacking compute circuits 906 and sensors 902 on the back of display 904, the overall footprint occupied by sensors 902, display 904, and compute circuits 906 can be reduced, especially compared with a case where sensors 902, display 904, and compute circuits are scattered at different locations within mobile device 800. The stacking arrangements are also likely to achieve the minimum and optimum overall footprint, given that display 904 typically have the largest footprint compared with sensors 902 and compute circuits 906, and that image sensors 902a can be oriented to face an opposite direction from display to provide simulated vision.

Moreover, in addition to improving the data transfer rate, the 2.5D/3D interconnects between the semiconductor substrates, such as interconnects 922a, 922b, and 924, also allow the data to be transferred more efficiently compared with, for example, discrete buses such as those defined under the MIPI specification. As a result, power consumption by the system in the data transfer can be reduced. For example, C-PHY Mobile Industry Processor Interface (MIPI) requires a few pico-Joule (pJ)/bit while wireless transmission through a 60 GHz link requires a few hundred pJ/bit. In contrast, due the high bandwidth and the short routing distance provided by the on-chip interconnects, the power consumed in the transfer of data over 2.5D/3D interconnects is typically just a fraction of pJ/bit. Furthermore, due to the higher transfer bandwidth and reduced transfer distance, the data transfer time can also be reduced as a result, which allows the support circuit components (e.g., clocking circuits, signal transmitter and receiver circuits) to be powered off for a longer duration to further reduce the overall power consumption of the system. All these can reduce the power consumption of integrated system 900 as well as mobile device 800 as a whole.

Some portions of this description describe the embodiments of the disclosure in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, and/or hardware.

Steps, operations, or processes described may be performed or implemented with one or more hardware or software modules, alone or in combination with other devices. In some embodiments, a software module is implemented with a computer program product comprising a computer-readable medium containing computer program code, which can be executed by a computer processor for performing any or all of the steps, operations, or processes described.

Embodiments of the disclosure may also relate to an apparatus for performing the operations described. The apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments of the disclosure may also relate to a product that is produced by a computing process described herein. Such a product may comprise information resulting from a computing process, where the information is stored on a non-transitory, tangible computer readable storage medium and may include any embodiment of a computer program product or other data combination described herein.

The language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the embodiments is intended to be illustrative, but not limiting, of the scope of the disclosure, which is set forth in the following claims.

That which is claimed is:

1. An apparatus comprising:
a first semiconductor layer that includes an image sensor;
a second semiconductor layer that includes a display;
a third semiconductor layer that includes compute circuits configured to support an image sensing operation by the image sensor and a display operation by the display; and
a semiconductor package that encloses the first, second, and third semiconductor layers, the semiconductor package further including a first opening to expose the image sensor and a second opening to expose the display,
wherein the first, second, and third semiconductor layers form a first stack structure along a first axis; and
wherein the third semiconductor layer is sandwiched between the first semiconductor layer and the second semiconductor layer in the first stack structure.

2. The apparatus of claim 1, wherein the first semiconductor layer includes a first semiconductor substrate and a second semiconductor substrate forming a second stack structure along the first axis, the second stack structure being a part of the first stack structure;
wherein the first semiconductor substrate includes an array of pixel cells; and
wherein the second semiconductor substrates includes processing circuits to process outputs of the array of pixel cells.

3. The apparatus of claim 2, wherein the first semiconductor substrate includes at least one of silicon or germanium.

4. The apparatus of claim 1, wherein the first semiconductor layer further includes a motion sensor.

5. The apparatus of claim 4, wherein the first semiconductor layer includes a semiconductor substrate that includes:
a micro-electromechanical system (MEMS) to implement the motion sensor; and
a controller to control an operation of the MEMS and to collect sensor data from the MEMS.

6. The apparatus of claim 1, wherein the second semiconductor layer includes a semiconductor substrate that includes an array of light emitting diodes (LED) to form the display.

7. The apparatus of claim 6, wherein the semiconductor substrate forms a device layer; and
wherein the second semiconductor layer further includes a thin-film circuit layer on the device layer configured to transmit control signals to the array of LEDs.

8. The apparatus of claim 7, wherein the device layer comprises a groups III V material; and
wherein the thin-film circuit layer comprises indium gallium zinc oxide (IGZO) thin-film transistors (TFTs).

9. The apparatus of claim 2, wherein the compute circuits include a sensor compute circuit and a display compute circuit;
wherein the sensor compute circuit includes an image sensor controller configured to control the image sensor to perform the image sensing operation to generate a physical image frame; and
wherein the display compute circuit includes a content generation circuit configured to generate an output image frame based on the physical image frame, and a rendering circuit configured to control the display to display the output image frame.

10. The apparatus of claim 9, wherein the compute circuits include a frame buffer;
wherein the image sensor controller is configured to store the physical image frame in the frame buffer;
wherein the content generation circuit is configured to replace one or more pixels of the physical image frame in the frame buffer to generate the output image frame, and to store the output image frame in the frame buffer; and
wherein the rendering circuit is configured to read the output image frame from the frame buffer and to generate display control signals based on the output image frame read from the frame buffer.

11. The apparatus of claim 9, wherein the sensor compute circuit includes a sensor data processor configured to determine pixel locations of a region of interest (ROI) that enclose a target object in the physical image frame; and
wherein the image sensor controller is configured to enable a subset of pixel cells of an array of pixel cells of the image sensor to capture a subsequent physical frame based on the pixel locations of the ROI.

12. The apparatus of claim 11, wherein the content generation circuit is configured to generate the output image frame based on a detection of the target object by the sensor data processor.

13. The apparatus of claim 12, wherein the first semiconductor layer further includes a motion sensor;
wherein the sensor data processor is further configured to determine at least one of a state of motion or a location of the apparatus based on an output of the motion sensor; and
wherein the image sensor controller is configured to enable the subset of pixel cells based on the at least one of a state of motion or a location of the apparatus.

14. The apparatus of claim 13, wherein the content generation circuit is configured to generate the output image frame based on the at least one of a state of motion or a location of the apparatus.

15. The apparatus of claim 1, wherein the first semiconductor layer is connected to the third semiconductor layer via 3D interconnects.

16. The apparatus of claim 1, wherein the first semiconductor layer is connected to the third semiconductor layer via 2.5D interconnects.

17. The apparatus of claim 1, wherein the third semiconductor layer is connected to the second semiconductor layer via metal bumps.

18. The apparatus of claim 1, further comprising a laser diode adjacent to the image sensor and configured to project structured light.

19. The apparatus of claim 1, further comprising a light emitting diode (LED) adjacent to the display to support an eye-tracking operation.

20. The apparatus of claim 1, wherein the third semiconductor layer further includes a power management circuit.

21. The apparatus of claim 1, wherein:
the image sensor is divided into a plurality of tiles of image sensing elements;
the display is divided into a plurality of tiles of display elements;
a frame buffer of the compute circuits is divided into a plurality of tile frame buffers;
each tile frame buffer is directly connected to a corresponding tile of image sensing element and a corresponding tile of display elements;
each tile of image sensing elements is configured to store a subset of pixels of a physical image frame in the corresponding tile frame buffer; and
each tile of display elements is configured to output a subset of pixels of an output image frame stored in the corresponding tile frame buffer.

22. A method of generating an output image frame, comprising:
generating, using an image sensor, an input image frame, the image sensor comprising a plurality of image sensing elements, the image sensing elements being connected to a frame buffer which is also connected to display elements of a display;
storing, using the image sensing elements, pixels of the input image frame at the frame buffer;
replacing, by a content generator, at least some of the pixels of the input image frame stored at the frame buffer to generate the output image frame; and
controlling, by a rendering circuit, the display elements to fetch pixels of the output image frame from the frame buffer to display the output image frame.

23. The method of claim 22, wherein the image sensor comprising a plurality of tiles of image sensing elements, each tile of image sensing elements being connected to a corresponding tile frame buffer which is also connected to a corresponding tile of display elements of a display; and wherein:
storing the pixels of the input images comprises storing, using each tile of image sensing elements, a subset of pixels of the input image frame at the corresponding tile frame buffer in parallel;
replacing at least some of the pixels of the input image comprises replacing, by a content generator, at least some of the pixels of the input image frame stored at the tile frame buffers to generate the output image frame; and
controlling the display elements to fetch pixels of the output image comprises controlling, by the rendering circuit, each tile of display elements to fetch a subset of pixels of the output image frame from the corresponding tile frame buffer to display the output image frame.

24. A head-mounted display (“HMD”) device comprising:
a housing configured to be worn on a user's head; and
a sensing and display system integrated into the housing, the sensing and display system comprising:
a first semiconductor layer that includes an image sensor;
a second semiconductor layer that includes a display;
a third semiconductor layer that includes compute circuits configured to support an image sensing operation by the image sensor and a display operation by the display; and
a semiconductor package that encloses the first, second, and third semiconductor layers, the semiconductor package further including a first opening to expose the image sensor and a second opening to expose the display,
wherein the first, second, and third semiconductor layers form a first stack structure along a first axis; and
wherein the third semiconductor layer is sandwiched between the first semiconductor layer and the second semiconductor layer in the first stack structure.
